(19) United States
(12) Patent Application Publication
(10) Pub. No.: US 2026/0163535 A1
(43) Pub. Date: Jun. 11, 2026

(54) INTEGRATED RESISTIVE ELEMENT OPERATIVE AS SENSING UNIT WITH IMPROVED SENSING ACCURACY AND ELECTRONIC APPARATUS COMPRISING THE SAME

(71) Applicant: Monolithic Power Systems, Inc., Kirkland, WA (US)

(72) Inventors: Wei-Chung Chen, Zhubei City (TW); Yu-Huei Lee, Zhubei City (TW)

(21) Appl. No.: 19/407,623

(22) Filed: Dec. 3, 2025

Related U.S. Application Data
(60) Provisional application No. 63/729,000, filed on Dec. 6, 2024.

(51) Int. Cl. H03F 3/187; G01R 27/08; G05F 1/56

(52) U.S. Cl. CPC H03F 3/187; G01R 27/08; G05F 1/56; H03F 2200/03

(57) ABSTRACT

An integrated resistive element adapted to be configured as an integrated sensing unit and electronic apparatus including the same. The integrated resistive element in an embodiment may include a plurality of resistive segments including a first portion disposed in or on a first well formed in a substrate and a second portion disposed in or on a second well formed in the substrate. The second portion is for being electrically coupled between a first terminal and a sensing terminal of the integrated resistive element. The first portion is for being electrically coupled between the sensing terminal and a second terminal of the integrated resistive element.

### CROSS-REFERENCE TO RELATED APPLICATIONS

The present application claims priority to U.S. Provisional Patent Application Ser. No. 63/729,000, filed on Dec. 6, 2024 which is incorporated herein by reference in its entirety.

### TECHNICAL FIELD

This disclosure relates generally to electrical devices, and more particularly but not exclusively relates to integrated resistive elements and related electronic apparatus.

### BACKGROUND

With the integration density for electric/electronic apparatus continuously desired to be increasing, resistive sensing circuits such as resistive voltage dividers are integrated inside an integrated circuit (“IC”), for example, formed in a semiconductor die with various other circuit elements formed therein. A resistive voltage divider is generally used to sense a voltage applied across the resistive voltage divider to provide a sensed voltage. The sensed voltage is indicative of the voltage applied across the resistive voltage divider and may be used for instance for controlling operation of an apparatus. Certain applications are sensitive to the sensed signal from the resistive sensing circuit and thus an integrated resistive sensing circuit with improved sensing accuracy is desired.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a top plan view layout diagram of an integrated resistive element 100 in accordance with an embodiment of the present invention.

FIG. 2 illustrates an equivalent circuit schematic diagram 200 of the integrated resistive element 100 in accordance with an embodiment of the present invention when configured as the resistive sensing unit described with reference to the example of FIG. 1.

FIG. 3 illustrates a waveform diagram 300 illustrating a practical curve 301 of the sensing voltage Vs versus the voltage Vab across the integrated resistive element 100 and a theoretically ideal curve 302 of the sensing voltage Vs versus the voltage across Vab across the integrated resistive element 100.

FIG. 4 illustrates a top plan view layout diagram of an integrated resistive element 400 in accordance with an embodiment of the present invention.

FIG. 5 illustrates a partial cross-sectional view of the integrated resistive element 400 in accordance with an embodiment of the present invention.

FIG. 6 illustrates a partial cross-sectional view of the integrated resistive element 400 in accordance with an alternative embodiment of the present invention.

FIG. 7 illustrates an equivalent circuit schematic diagram 700 of the integrated resistive element 400 in accordance with an embodiment of the present invention when configured as the resistive sensing unit described with reference to the examples showing in FIG. 4, FIG. 5 and FIG. 6.

FIG. 8 illustrates a waveform diagram 800 illustrating a practical curve 801 of the sensing voltage Vs versus the voltage Vab across the integrated resistive element 400 and a theoretically ideal curve 802 of the sensing voltage Vs versus the voltage across Vab across the integrated resistive element 400.

FIG. 9 illustrates a top plan view layout diagram of an integrated resistive element 900 in accordance with an embodiment of the present invention.

FIG. 10 illustrates an equivalent circuit schematic diagram 1000 of the integrated resistive element 900 in accordance with an embodiment of the present invention when configured as the resistive sensing unit described with reference to the example shown in FIG. 9.

FIG. 11 illustrates an equivalent circuit schematic diagram 1100 of the integrated resistive element 900 in accordance with an alternative embodiment of the present invention when configured as the resistive sensing unit.

FIG. 11A illustrates a top plan view layout diagram of an integrated resistive element 100A in accordance with an exemplary embodiment of the present invention.

FIG. 11B illustrates an equivalent circuit schematic diagram 100B of the integrated resistive element 100A in accordance with such an exemplary embodiment of the present invention when configured as the resistive sensing unit.

FIG. 12 illustrates a top plan view layout diagram of an integrated resistive element 1200 in accordance with an embodiment of the present invention.

FIG. 13 illustrates an equivalent circuit schematic diagram 1300 of the integrated resistive element 1200 in accordance with an embodiment of the present invention when configured as the resistive sensing unit described with reference to the example shown in FIG. 12.

FIG. 14 illustrates a partial cross-sectional view of the integrated resistive element 1200 in accordance with an embodiment of the present invention.

FIG. 15 illustrates a partial cross-sectional view of the integrated resistive element 1200 in accordance with an alternative embodiment of the present invention.

FIG. 16 illustrates an equivalent circuit schematic diagram 1600 of an integrated resistive element 1600 in accordance with an embodiment of the present invention when configured as a resistive sensing unit.

FIG. 17 illustrates an equivalent circuit schematic diagram 1700 of an integrated resistive element 1700 in accordance with an embodiment of the present invention when configured as a resistive sensing unit.

FIG. 18 illustrates a top plan view layout diagram of an integrated resistive element 1800 in accordance with an embodiment of the present invention.

FIG. 18A illustrates a top plan view layout diagram of an integrated resistive element 1800A in accordance with another exemplary embodiment of the present invention.

FIG. 19 illustrates a partial cross-sectional view of the integrated resistive element 1800 in accordance with an embodiment of the present invention.

FIG. 20 illustrates an equivalent circuit schematic diagram 2000 of the integrated resistive element 1800 in accordance with an embodiment of the present invention when configured as the resistive sensing unit described with reference to the examples shown in FIG. 18 and FIG. 19.

FIG. 20A illustrates an equivalent circuit schematic diagram 2000A of the integrated resistive element 1800A in accordance with an embodiment of the present invention when configured as the resistive sensing unit described with reference to the example shown in FIG. 18A.

FIG. 21 illustrates a block diagram of a power management apparatus 2100 in accordance with an embodiment of the present invention.

FIG. 22 illustrates a block diagram of a power management apparatus 2200 in accordance with an alternative embodiment of the present invention.

FIG. 23 illustrates a block diagram of a power management apparatus 2300 in accordance with an alternative embodiment of the present invention.

FIG. 24 illustrates a block diagram of a power management apparatus 2400 in accordance with an alternative embodiment of the present invention.

FIG. 25 illustrates a waveform diagram of several signals of the power management apparatus 2400 during operation.

FIG. 26 illustrates a block diagram of a linear voltage regulator 2600 in accordance with an embodiment of the present invention.

FIG. 27 illustrates a block diagram of an audio amplifier 2700 in accordance with an embodiment of the present invention.

FIG. 28 illustrates a waveform diagram 2800 illustrating a practical curve 2801 of an amplitude of the amplification gain G1 of the audio amplifier 2700 versus the input signal Vsig provided to the audio amplifier 2700 and a theoretically ideal curve 2802 of the amplitude of the amplification gain G1 of the audio amplifier 2700 versus the input signal Vsig.

FIG. 29 illustrates a block diagram of an audio amplifier 2900 in accordance with an alternative embodiment of the present invention.

FIG. 30 illustrates a waveform diagram 3000 illustrating a practical curve 3001 of an amplitude of the amplification gain G2 of the audio amplifier 2900 versus the input signal Vsig provided to the audio amplifier 2900 and a theoretically ideal curve 3002 of the amplitude of the amplification gain G2 of the audio amplifier 2900 versus the input signal Vsig.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled,” as used herein, is defined as directly or indirectly connected in an electrical or non-electrical manner. When an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. In addition, “electrically connected” or “electrically coupled” means the concept including a physical connection and a physical disconnection, which enables an electrical coupling between elements. It can be understood that when an element is referred to with “first” or “second” or the like, the element is not limited thereby. The terms “first” or “second” or the like may be used only for a purpose of distinguishing the element from the other elements being modified by these terms and may not limit the sequence or importance of the elements being modified unless the context clearly dictates otherwise. The terms “a,” “an,” and “the” include plural reference, and the term “in” includes “in” and “on” unless the context clearly dictates otherwise. The phrase “in one embodiment,” as used herein does not necessarily refer to the same embodiment, although it may. The term “or” is an inclusive “or” operator, and is equivalent to the term “and/or” herein, unless the context clearly dictates otherwise. The term “and/or” may include individual or any combination of the elements being referenced in conjunction with the term. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus.

The terms “left,” right,“ ”in,“ ”out,“ ”front,“ ”back,“ ”up,“ ”down, “top,” “atop”, “bottom,” “over,” “under,” “above,” “below”, “lower”, “upper” and the like in the description and the claims, if any, are used for descriptive purposes and for convenience of explanation and not necessarily for describing permanent relative positions. It is to be understood that the terms so used are interchangeable under appropriate circumstances such that embodiments of the invention described herein are, for example, capable of operation in other orientations than those illustrated or otherwise described herein, and the claims are not particularly limited by the positions or directions as described with those terms.

For convenience of explanation, the present disclosure may take a specific semiconductor device as an example for the explanation, but this is not intended to be limiting and persons of skill in the art will understand that the structure and principles taught herein also apply to other semiconductor devices.

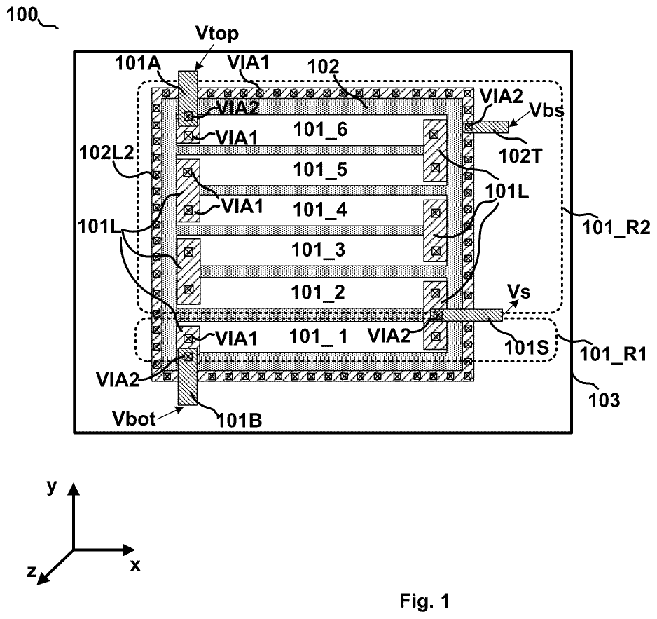

FIG. 1 illustrates a top plan view layout diagram of an integrated resistive element 100 in accordance with an embodiment of the present invention. For the illustration of FIG. 1, the integrated resistive element 100 is illustrated in a coordinate system defined by the x, y and z axes that are perpendicular to each other, and the perspective view observed from a conductive routing layer such as a metal routing layer of the integrated resistive element 100 in the x-y plane is shown. The integrated resistive element 100 is formed in or on a semiconductor substrate 103 of a semiconductor die. In one embodiment, the conductive routing layer may involve or constitute a portion of a conductive routing structure that may include one or more conductive routing layers formed on the substrate 101. An inter-layer dielectric layer (“ILD”) may be formed between any two adjacent conductive routing layers (i.e., the conductive routing layers that are adjacent to each other in the z-axis direction) of the conductive routing structure. It can be easily understood that a view inspected from the x-y plane may be referred to as a plan view while a view inspected from a sectional cut along the z-axis direction may be referred to as a cross-sectional view throughout the present disclosure. For the purpose of clarity, the ILD is not shown in FIG. 1, and the conductive routing layer that is disposed closest (in comparison to other conductive routing layers of the conductive routing structure) to the substrate 103 in the z-axis dimension is illustrated out. In an embodiment, the semiconductor substrate 103 may be of a first conductivity type, for instance P type in an example. In an embodiment, the semiconductor substrate 103 may comprise one or more of the semiconductor materials such as Si, Ge, SiC, or other forms of semiconductor layers. The substrate 103 may alternatively include silicon-on-insulator (SOI) substrate or other forms of substrate that are compatible with the operation and manufacturing process of the integrated resistive element 100.

The integrated resistive element 100 may include a plurality of resistive segments 101_1, 101_2, . . . , 101_6, and a well 102. The well 102 is formed in the semiconductor substrate 103. The well 102 may be of a second conductivity type that is opposite to the first conductivity type. For instance, the well 102 may be of an N type in an example. The well 102 may be electrically coupled to a well bus 102L and/or a well terminal 102T so that the well 102 can be electrically coupled to other signals or circuit elements. In an embodiment, the well bus 102L and the well terminal 102T may be formed in different conductive routing layers (e.g., different metal routing layers) formed on the substrate 103. As illustratively shown in FIG. 1, the well bus 102L may be formed in a first conductive routing layer (e.g., a first metal routing layer) that is illustrated by trace(s) filled with sparse diagonal lines while the well terminal 102T may be formed in a second conductive routing layer (e.g., a second metal routing layer) that is illustrated by trace(s) filled with tighter diagonal lines. In an embodiment, referring to the example illustratively shown in FIG. 1, the well 102 may be electrically coupled to the well bus 102L through a plurality of interlayer routing elements such as interlayer vias VIA1 (e.g., illustrated by a plurality of small squares in FIG. 1) formed in a first interlayer dielectric layer (“IDL”) disposed between the substrate 103 and the well bus 102L (or the first conductive routing layer that includes the well bus 102L) with the plurality of interlayer vias VIA1 being filled with electrically conductive materials. The well bus 102L and the well terminal 102T may be electrically coupled for instance by one or more interlayer routing elements such as interlayer vias VIA2 (e.g., illustrated by a plurality of small squares in FIG. 1) formed in a second IDL which is disposed on the first IDL or between the first and the second conductive routing layers, with the one or one interlayer vias VIA2 being filled with conductive materials. In an embodiment, as illustratively shown in FIG. 1, the well bus 102L may be routed above and along a perimeter (or a boundary) of the well 102 when inspected in a plan view (i.e., from the x-y plane view).

In an embodiment, still refer to FIG. 1, the plurality of resistive segments 101_1, 101_2, . . . , 101_6 are disposed in or on the well 102, for instance within the perimeter (or the boundary) of the well 102, and may be arranged in an array or a matrix. In an embodiment, the plurality of resistive segments 101_1, 101_2, . . . , 101_6 may substantially be identical to each other in perspectives of a geometry shape and/or a geometry size. That is, each one of the plurality of resistive segments 101_1, 101_2, . . . , 101_6 may have a shape and/or a size that are substantially identical to those of each one of the rests of the plurality of resistive segments 101_1, 101_2, . . . , 101_6, for instance, with a mismatching margin of within ±2% in an embodiment. In this fashion, it can be well understood by those of ordinary skill in the art that the plurality of resistive segments 101_1, 101_2, . . . , 101_6 have substantially identical resistance to each other. That is, each one of the plurality of resistive segments 101_1, 101_2, . . . , 101_6 may have a resistance that is substantially identical to a resistance of each one of the rests of the plurality of resistive segments 101_1, 101_2, . . . , 101_6. The plurality of resistive segments 101_1, 101_2, . . . , 101_6 may be electrically coupled with each other. For instance, in addition to the well bus 102L, the first conductive routing layer (e.g., the first metal routing layer) of the integrated resistive element 100 further includes a plurality of conductive connecting segments 101L to electrically couple the plurality of resistive segments 101_1, 101_2, . . . , 101_6 with each other. The well bus 102L may run surrounding the plurality of conductive connecting segments 101L when inspected in a plan view (i.e., from the x-y plane view) according to an exemplary embodiment as shown in FIG. 1. In an embodiment, each of the plurality of conductive connecting segments 101L may include a metal connecting segment. Each of the plurality of conductive connecting segments 101L may be electrically coupled to ends of every two resistive segments that are arranged immediately adjacent to each other among the plurality of resistive segments 101_1, 101_2, . . . , 101_6, for example, through some of the plurality of interlayer routing elements (e.g., interlayer vias) VIA1 formed in the first IDL which is disposed between the substrate 103 and the first conductive routing layer. Although six resistive segments 101_1, 101_2, . . . , 101_6 are illustrated out in the example of FIG. 1, it can be understood by one of ordinary skill in the art that the integrated resistive element 100 may include any suitable number of resistive segments according to practical application and/or design requirements.

The integrated resistive element 100 may have a first terminal 101A and a second terminal 101B adapted to be used to enable connection of the resistive element 100 to other signals or circuit elements. The plurality of resistive segments 101_1, 101_2, . . . , 101_6 are electrically coupled in series with each other between the first terminal 101A and the second terminal 101B of the integrated resistive element 100. The first terminal 101A and the second terminal 101B may be formed in the second conductive routing layer (e.g., the second metal routing layer) that includes the well terminal 102T according to an exemplary embodiment as shown in FIG. 1. The first terminal 101A may be electrically coupled to a last one resistive segment (e.g., the one labeled with 101_6 in the example of FIG. 1) in the array or the matrix of the plurality of resistive segments 101_1, 101_2, . . . , 101_6, for example, through one or more of the interlayer routing elements such as interlayer vias VIA2 (e.g., illustrated by a plurality of small squares in FIG. 1) formed in the second IDL, a conductive connecting segment in the first conductive routing layer, and one or more of the interlayer routing elements such as interlayer vias VIA1 (e.g., illustrated by a plurality of small squares in FIG. 1) formed in the first IDL disposed between the first conductive routing layer and the substrate 103. Similarly, the second terminal 101B may be electrically coupled to a first one resistive segment (e.g., the one labeled with 101_1 in the example of FIG. 1) in the array or the matrix of the plurality of resistive segments 101_1, 101_2, . . . , 101_6, for example, through one or more of the interlayer routing elements such as interlayer vias VIA2 (e.g., illustrated by a plurality of small squares in FIG. 1) formed in the second IDL, a conductive connecting segment in the first conductive routing layer, and one or more of the interlayer routing elements such as interlayer vias VIA1 (e.g., illustrated by a plurality of small squares in FIG. 1) formed in the first IDL disposed between the first conductive routing layer and the substrate 103.

A resistance of the integrated resistive element 100 generally depends on a bias voltage Vbs that may be applied to the well 102 via for example the well terminal 102T and a voltage Vab across the resistive element 100 that is a voltage difference between a first voltage Vtop and a second voltage Vbot that may be applied respectively from the first terminal 101A and the second terminal 101B of the integrated resistive element 100 in the example of FIG. 1. In this example, Vab=Vtop−Vbot.

In an embodiment, the integrated resistive element 100 may be configured to form a resistive sensing unit to provide a sensing voltage Vs that is indicative of the voltage Vab across the integrated resistive element 100 with the second voltage Vbot at the second terminal 101B taken as a reference potential of the resistive sensing unit (including all the sub-circuits and elements that the resistive sensing unit may comprise). That is, Vs=Ga*Vab+Vbot=Ga*(Vtop−Vbot)+Vbot, wherein Ga is a sensing gain of the resistive sensing unit. Those skilled in the art would understand that the first voltage Vtop, the second voltage Vbot, and the sensing voltage Vs are all mentioned relative to a ground potential of a ground GND. In an embodiment, to provide an example, the second terminal 101B of the integrated resistive element 100 may be connected to the ground GND, which means the second voltage Vbot is set to the ground voltage potential (i.e., Vbot=0V) and thus Vs=Ga*Vab=Ga*Vtop for such an example.

In an embodiment, for instance, a sensing terminal 101S that is disposed between a first portion 101_R1 of the plurality of resistive segments 101_1, 101_2, . . . , 101_6 and a second portion 101_R2 of the plurality of resistive segments 101_1, 101_2, . . . , 101_6 may be electrically led out from the integrated resistive element 100 to provide the sensing voltage Vs at the sensing terminal 101S. The sensing terminal 101S is electrically coupled to the first portion 101_R1 and the second portion 101_R 2. The first portion 101_R1 may include a first set of the resistive segments among the plurality of resistive segments 101_1, 101_2, . . . , 101_6. The second portion 101_R2 may include a second set of the resistive segments among the plurality of resistive segments 101_1, 101_2, . . . , 101_6. In the example of FIG. 1, the first portion 101_R1 or the first set of the resistive segments is illustrated to include the resistive segment 101_1 while the second portion 101_R2 or the second set of the resistive segments is illustrated to include the resistive segments 101_2, . . . , 101_6. The sensing terminal 101S may be electrically coupled to a starting one resistive segment (e.g., the one labeled with 101_2 in the example of FIG. 1) in the second portion 101_R2 including the second set of the resistive segments 101_2, . . . , 101_6 according to the embodiment of FIG. 1, for example, through one or more of the interlayer routing elements such as interlayer vias VIA2 (e.g., illustrated by a plurality of small squares in FIG. 1) formed in the second IDL, a conductive connecting segment in the first conductive routing layer, and one or more of the interlayer routing elements such as interlayer vias VIA1 (e.g., illustrated by a plurality of small squares in FIG. 1) formed in the first IDL disposed between the first conductive routing layer and the substrate 103. Similarly, The sensing terminal 101S may be electrically coupled to an ending one resistive segment (e.g., the one labeled with 101_1 in the example of FIG. 1) in the first portion 101_R1 including the first set of the resistive segments 101_1 according to the embodiment of FIG. 1, for example, through one or more of the interlayer routing elements such as interlayer vias VIA2 (e.g., illustrated by a plurality of small squares in FIG. 1) formed in the second IDL, a conductive connecting segment in the first conductive routing layer, and one or more of the interlayer routing elements such as interlayer vias VIA1 (e.g., illustrated by a plurality of small squares in FIG. 1) formed in the first IDL disposed between the first conductive routing layer and the substrate 103. However, this is just for illustrative and exemplary purpose to help those skilled in the art to understand embodiments of the present disclosure and is not intended to be limiting. For instance, in other embodiments, the first portion 101_R1 or the first set of the resistive segments may include more than one resistive segment. The number of resistive segments in the first set of resistive segments included in the first portion 101_R1 and the number of resistive segments in the second set of resistive segments included in the second portion 101_R2 may be properly chosen according to practical application or design requirements for example depending on the sensing gain Ga of the resistive sensing unit to be implemented. The sensing gain Ga of the resistive sensing unit may be expressed as Ga=(Vs−Vbot)/Vab. An accuracy of the sensing voltage Vs depends on a linearity of a resistance ratio K between a first resistance R1 of the first portion 101_R1 and a second resistance R2 of the second portion 101_R 2 while the linearity of the resistance ratio K depends on the bias voltage Vbs that may be applied to the well terminal 102T of the well 102 and the voltage Vab across the integrated resistive element 100. The resistance ratio K may be expressed by K=R2/R1 in this example. The first resistance R1 depends on the number of resistive segments that are included in the first portion 101_R1. The second resistance R2 depends on the number of resistive segments that are included in the second portion 101_R2.

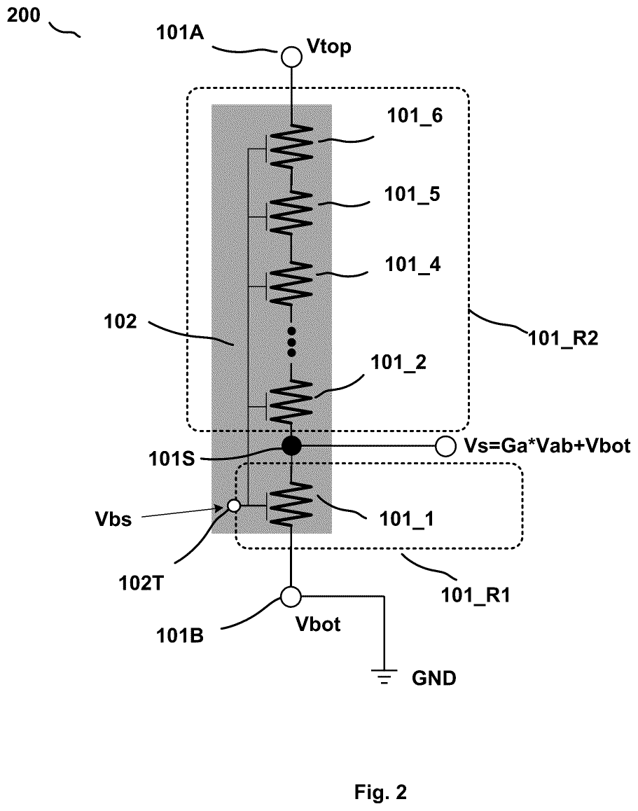

FIG. 2 illustrates an equivalent circuit schematic diagram 200 of the integrated resistive element 100 in accordance with an embodiment of the present invention when configured as the resistive sensing unit described with reference to the example of FIG. 1.

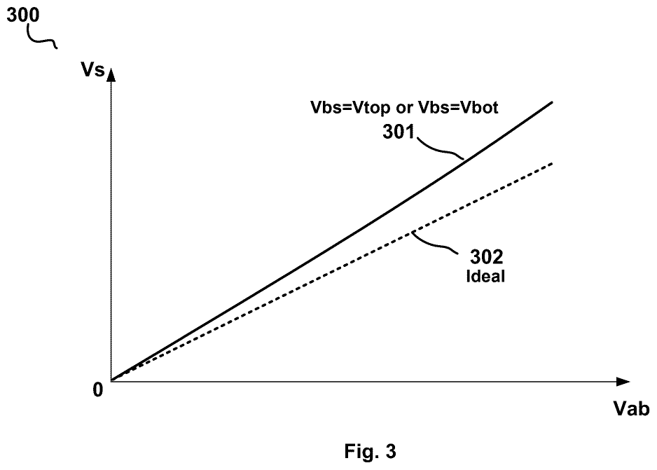

FIG. 3 illustrates a waveform diagram 300 illustrating a practical curve 301 of the sensing voltage Vs versus the voltage Vab across the integrated resistive element 100 when the bias voltage Vbs applied to the well 102 is set to the first voltage Vtop or to the second voltage Vbot and a theoretically ideal curve 302 of the sensing voltage Vs versus the voltage Vab across the integrated resistive element 100. As illustrated with the practical curve 301, the sensing voltage Vs may not linearly change with the voltage Vab across the integrated resistive element 100 in practical applications when the bias voltage Vbs applied to the well 102 is set to the first voltage Vtop or to the second voltage Vbot, and the non-linearity becomes more obvious with the voltage Vab across the integrated resistive element 100 increasing and/or the sensing voltage Vs needed getting relatively low (e.g., Vs<Vab/3 or Ga<1/3 in an example, Vs<Vab/10 or Ga<1/10 in another example, Vs<Vab/20 or Ga<1/20 in still another example) according to practical application requirements. It is however expected or desired that the practical curve 301 should infinitely approach or match with the ideal curve 302 so that the sensing voltage Vs provided by the resistive sensing unit can accurately indicate the voltage Vab across the integrated resistive element 100 with a substantially simple linear relationship depending on the resistance ratio K. One of ordinary skill in the art would understand that the well terminal 102T operative to receive the bias voltage Vbs at least, in one aspect, makes it possible to improve the linearity of the resistance ratio K between multiple portions (e.g. the first portion 101_R1 and the second portion 101_R2 in the examples) of the integrated resistive element (e.g., 100) by adjusting or tuning the bias voltage Vbs, for example by setting the bias voltage Vbs to a voltage value between the first voltage Vtop and the second voltage Vbot. In another aspect, the integrated resistive element (e.g., 100) of the present disclosure when being operated to form a resistive sensing unit may at least be beneficial to improving the accuracy of the sensing voltage Vs (e.g., the linearity of the relationship between the sensing voltage Vs versus the voltage Vab) by adjusting or tuning the bias voltage Vbs, for example by setting the bias voltage Vbs to a voltage value between the first voltage Vtop and the second voltage Vbot.

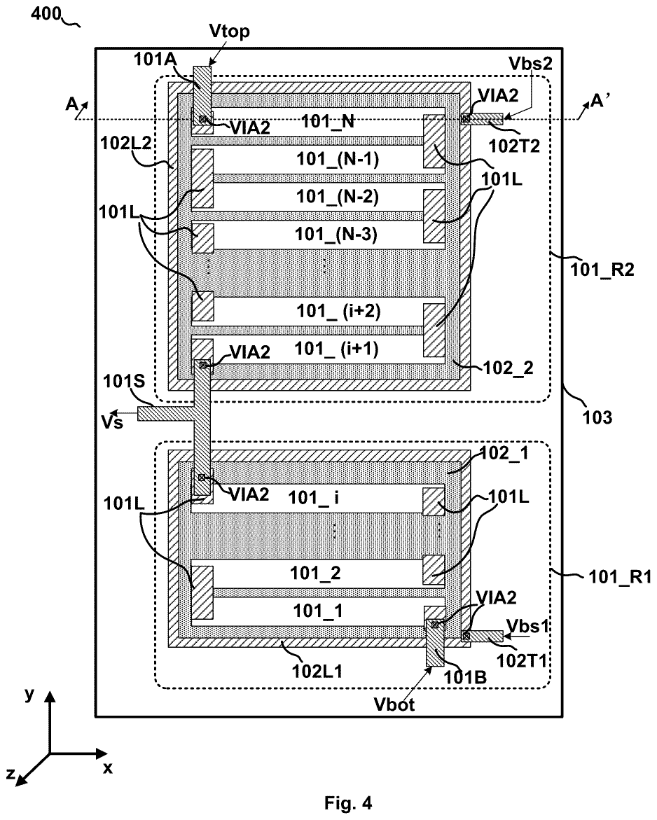

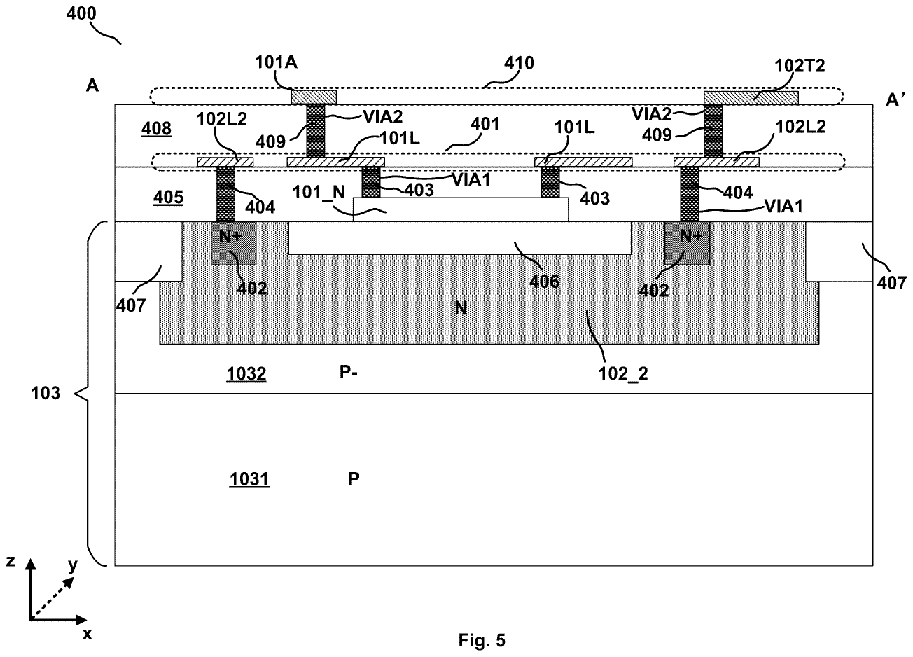

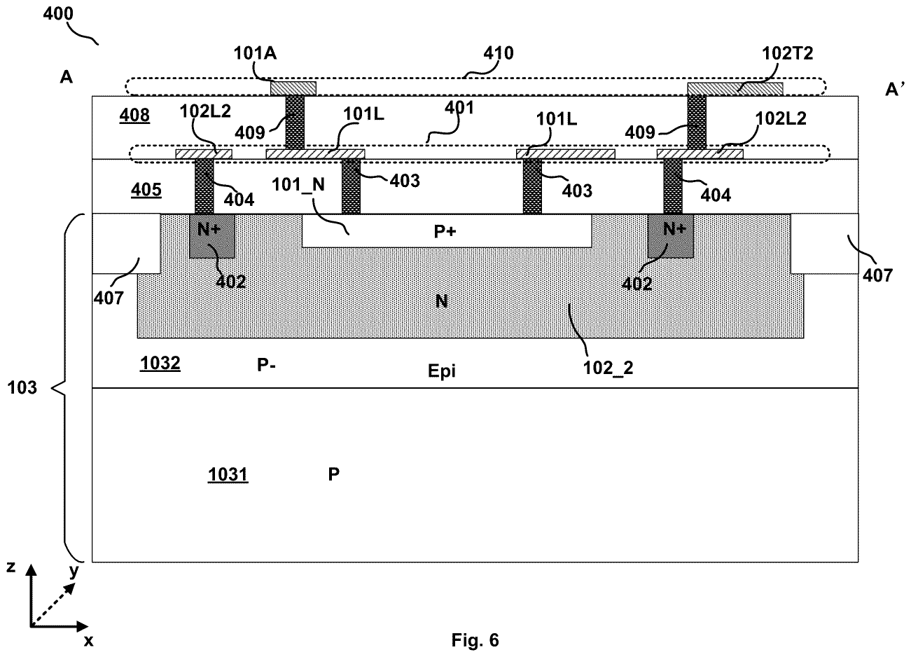

FIG. 4 illustrates a top plan view layout diagram of an integrated resistive element 400 in accordance with an embodiment of the present invention. FIG. 5 illustrates a partial cross-sectional view of the integrated resistive element 400 in accordance with an embodiment of the present invention. FIG. 6 illustrates a partial cross-sectional view of the integrated resistive element 400 in accordance with an alternative embodiment of the present invention. It may be understood that the illustrative cross-sectional views of FIG. 5 and FIG. 6 may be considered as taken along the cutting line A-A′ in the top plan view of FIG. 4. For the sake of not obscuring certain features of the embodiments, in the top plan view of FIG. 4, the plurality of interlayer routing elements (such as interlayer vias VIA1 filled with electrically conductive materials) formed in the first interlayer dielectric layer (“IDL”) are not shown but can be well understood with further reference to FIG. 1 in conjunction with FIG. 5 and FIG. 6.

The integrated resistive element 400 may include a plurality of resistive segments 101_1, . . . , 101_N. In the example shown in FIG. 4, a total number of the plurality of resistive segments 101_1, . . . , 101_N that the integrated resistive element 400 includes is more generically represented by a variable N which is an integer greater than 1 and has a value that can be chosen or designed according to practical application and/or design requirements. Those of ordinary skill in the art would understand that most descriptions made to the integrated resistive element 100 may be applicable to the integrated resistive element 400 except that in one aspect the total number of the plurality of resistive segments 101_1, . . . , 101_N that the integrated resistive element 400 includes is extended to be more generically indicated by the variable N. And various embodiments such as the integrated resistive element 100 and the integrated resistive element 400 can be better understood in conjunction with the cross-sectional views illustrated in FIG. 5 and FIG. 6. For instance, the plurality of (e.g., N) resistive segments 101_1, . . . , 101_N may be electrically coupled with each other by a plurality of conductive connecting segments 101L formed in a first conductive routing layer 401 (which can also be understood in conjunction with the cross-sectional illustrations in FIG. 5 and FIG. 6) of the integrated resistive element 400. In an exemplary embodiment, the first conductive routing layer 401 may include or be embodied as a first metal routing layer. In an embodiment, the plurality of (e.g., N) resistive segments 101_1, . . . , 101_N may substantially be identical to each other in perspectives of a geometry shape and/or a geometry size. That is, each one of the plurality of (e.g., N) resistive segments 101_1, . . . , 101_N may have a shape and/or a size that are substantially identical to those of each one of the rest of the plurality of resistive segments 101_1, . . . , 101_N, for instance, with a mismatching margin of within ±2% in an embodiment. In this fashion, it can be well understood by those of ordinary skill in the art that the plurality of resistive segments 101_1, . . . , 101_N have substantially identical resistance to each other. That is, each one of the plurality of resistive segments 101_1, . . . , 101_N may have a resistance that is substantially identical to a resistance of each one of the rests of the plurality of resistive segments 101_1, . . . , 101_N. The plurality of (e.g., N) resistive segments 101_1, . . . , 101_N may be divided to include a first portion 101_R1 including a first set of resistive segments that may be arranged in a first array or a first matrix and a second portion 101_R2 including a second set of resistive segments that may be arranged in a second array or a second matrix.

Similarly as described with reference to the integrated resistive element 100 of FIG. 1, the integrated resistive element 400 may be configured to form a resistive sensing unit to provide a sensing voltage Vs. The sensing terminal 101S may be electrically coupled to an ending one resistive segment (e.g., the one labeled with 101_i in the example of FIG. 4) in the first portion 101_R1 including the first set of the resistive segments 101_1, . . . , 101_i and to a starting one resistive segment (e.g., the one labeled with 101_(i+1) in the example of FIG. 4) in the second portion 101_R2 including the second set of the resistive segments 101_(i+1), . . . , 101_N according to the embodiment of FIG. 4. Those skilled in the art would understand that more details and substantial descriptions related to configuring the integrated resistive element 100 to form the resistive sensing unit as described above with reference to the example of FIG. 1 are applicable to the example of FIG. 4 to configure the integrated resistive element 400 to form the resistive sensing unit and need not to be addressed again here for simplicity. In the example shown in FIG. 4, the first portion 101_R1 or the first set of the resistive segments is more generically illustrated to include the resistive segments 101_1, . . . , 101_i while the second portion 101_R2 or the second set of the resistive segments is more generically illustrated to include the resistive segments 101_(i+1), . . . , 101_N. Here, the variable i is an integer indicative of the number of the resistive segments that are included in the first portion 101_R1 (i.e., the first set of the resistive segments) and may have a value that can be set or predetermined according to the sensing voltage Vs that is desired to be provided or the sensing gain Ga. The first resistance R1 depends on the number i of resistive segments that are included in the first portion 101_R1. The second resistance R2 depends on the number (N−i) of resistive segments that are included in the second portion 101_R2. In an example, the variable i may have a value set according to the sensing gain Ga and the total number N of the plurality of resistive segments 101_1, . . . 101_N included in the integrated resistive element 400. For instance, the variable i may be set between 1 and N in the example shown in FIG. 4, and may satisfy the expression of Ga=i/N. This is just for illustrative and exemplary purpose to help those skilled in the art to understand embodiments of the present disclosure and is not intended to be limiting. The number i of resistive segments in the first set of resistive segments included in the first portion 101_R1 and the number (N−i) of resistive segments in the second set of resistive segments included in the second portion 101_R2 may be properly chosen according to practical application or design requirements for example depending on the sensing gain Ga of the resistive sensing unit to be implemented.

In another aspect, compared with the integrated resistive element 100 shown in FIG. 1, in the integrated resistive element 400 as illustratively shown in FIG. 4, the well 102 is split or divided into a first well 102_1 and a second well 102_2 that respectively correspond to the first portion 101_R1 and the second portion 101_R 2 of the plurality of resistive segments 101_1, 101_2, . . . , 101_N. That is, the first portion 101_R1 of the plurality of resistive segments 101_1, 101_2, . . . , 101_N is disposed in or on the first well 102_1 for instance within the perimeter (or the boundary) of the first well 102_1 and the second portion 101_R2 of the plurality of resistive segments 101_1, 101_2, . . . , 101_N is disposed in or on the second well 102_2 for instance within the perimeter (or the boundary) of the second well 102_2. The first well 102_1 and the second well 102_2 are separated and electrically isolated from each other. The first conductive routing layer (labeled with 401 and can be better understood in conjunction with the cross-sectional illustrations in FIG. 5 and FIG. 6) of the integrated resistive element 400 includes the plurality of conductive connecting segments 101L to electrically couple the plurality of resistive segments 101_1, 101_2, . . . , 101_N with each other. The first conductive routing layer 401 of the integrated resistive element 400 may further include a first well bus 102L1 and a second well bus 102L2 that are separated and electrically isolated from each other. In an embodiment, as illustratively shown in FIG. 4, the first well bus 102L1 may be routed above and along a perimeter (or a boundary) of the first well 102_1 while the second well bus 102L2 may be routed above and along a perimeter (or a boundary) of the second well 102_2 when inspected in a plan view (i.e., from the x-y plane view). In an embodiment, the first well bus 102L1 may run surrounding a first set of conductive connecting segments among the plurality of conductive connecting segments 101L while the second well bus 102L2 may run surrounding a second set of conductive connecting segments among the plurality of conductive connecting segments 101L when inspected in a plan view (i.e., from the x-y plane view) according to an exemplary embodiment as shown in FIG. 4. It can easily be understood by those of ordinary skill in the art that the first set of conductive connecting segments among the plurality of conductive connecting segments 101L are configured to electrically couple the first set of resistive segments 101_1, . . . , 101_i in series and the second set of conductive connecting segments among the plurality of conductive connecting segments 101L are configured to electrically couple the second set of resistive segments 101_(i+1), . . . , 101_N in series.

In the exemplary embodiment shown in FIG. 4, the first well 102_1 may be electrically coupled to the first well bus 102L1 and/or a first well terminal 102T1 and the second well 102_2 may be electrically coupled to the second well bus 102L2 and/or a second well terminal 102T2. One of ordinary skill in the art would understand that the example illustrated in FIG. 4 may also be considered as an alternative from the embodiment shown in FIG. 1 with the well bus 102L split into the first well bus 102L1 and the second well bus 102L2 and with the well terminal 102T split into the first terminal 102T1 and the second terminal 102T2 corresponding to the well 102 being split into the first well 102_1 and the second well 102_2. Those of ordinary skill in the art would understand that electrical couplings of the first well terminal 102T1 to the first well bus 102L1 and to the first well 102_1 and electrical couplings of the second well terminal 102T2 to the second well bus 102L2 and to the second well 102_2 in the example of FIG. 4 may be implemented similarly as the electrical couplings of the well terminal 102T to the well bus 102 and to the well 102 as described with reference to FIG. 1. In this manner, the first well 102_1 and the second well 102_2 may be configured to receive different bias voltages to improve the linearity of the resistance ratio K. This would enable to improve the accuracy of the sensing voltage Vs by adjusting the bias voltages applied to the first well 102_1 and the second well 102_2 separately and independently. For instance, the first well 102_1 may be electrically coupled to receive a first bias voltage Vbs1 that may be applied to the first well 102_1 via for example the first well terminal 102T1 and the first well bus 102L1, and the second well 102_2 may be electrically coupled to receive a second bias voltage Vbs2 that may be applied to the second well 102_2 via for example the second well terminal 102T2 and the second well bus 102L2. Those skilled in the art would understand that here the first bias voltage Vbs1 and the second bias voltage Vbs2 are also mentioned relative to the ground potential of the ground GND.

In accordance with an embodiment, the first bias voltage Vbs1 is different from the second bias voltage Vbs2. In an embodiment, the first bias voltage Vbs1 may not exceed a range from the second voltage Vbot to the second bias voltage Vbs2, that is, Vbs1∈[Vbot, Vbs2). In an embodiment, the first well terminal 102T1 may be coupled to the second terminal 101B of the integrated resistive element 400 so that the first bias voltage Vbs1 may substantially be set to the second voltage Vbot that is applied to the second terminal 101B of the integrated resistive element 400. In an embodiment, the first well terminal 102T1 may be coupled to the sensing terminal 101S so that the first bias voltage Vbs1 may substantially be set to the sensing voltage Vs. In an embodiment, the first bias voltage Vbs1 may be set between the sensing voltage Vs at the sensing terminal 101S and the second voltage Vbot that is applied to the second terminal 101B of the integrated resistive element 400, that is, Vbs1∈(Vbot, Vs). In an embodiment, the first bias voltage Vbs1 may be configured to be approaching to a middle value between the sensing voltage Vs and the second voltage Vbot that is [(Vs−Vbot)/2+Vbot] with a predetermined deviation margin for example of ±10% or of other appropriate value that may depend on practical application or design requirements. In an embodiment, the first bias voltage Vbs1 may be derived from the sensing voltage Vs with a first scale-down coefficient K1, for example., Vbs1=K1*(Vs−Vbot)+Vbot, wherein 0<K1<1. In an embodiment, the first scale-down coefficient K1 may be in a range from ⅓ to ⅔. In an embodiment, the first scale-down coefficient K1 may be substantially set to ½ with a predetermined deviation margin for example of ±10% or of other appropriate value that may depend on practical application or design requirements.

In an embodiment, the second terminal 101B of the integrated resistive element 400 may be connected to the ground GND having the ground voltage potential, which means the second voltage Vbot is set to the ground voltage potential (i.e., Vbot=0V) in this example.

In an embodiment, the second bias voltage Vbs2 may be set between the first bias voltage Vbs1 and the first voltage Vtop that is applied to the first terminal 101A of the integrated resistive element 400, that is, Vbs2∈(Vbs1, Vtop). In an embodiment, the second bias voltage Vbs2 may be set between the sensing voltage Vs at the sensing terminal 101S and the first voltage Vtop that is applied to the first terminal 101A of the integrated resistive element 400, that is, Vbs2∈(Vs, Vtop). In an embodiment, the second bias voltage Vbs2 may be configured to be in a range from (Vab/3+Vbot) to (2*Vab/3+Vbot) or in a range from [(Vtop−Vs)/3+Vs] to [2*(Vtop−Vs)/3+Vs]. In an embodiment, the second bias voltage Vbs2 may be configured to be substantially approaching to a middle value between the sensing voltage Vs and the first voltage Vtop that is [(Vtop−Vs)/2+Vs] with a predetermined deviation margin for example of ±10% or a middle value between the first bias voltage Vbs1 and the first voltage Vtop that is [(Vtop−Vbs1)/2+Vbs1] with a predetermined deviation margin for example of ±10% or a middle value between the second voltage Vbot and the first voltage Vtop that is (Vab/2+Vbot) with a predetermined deviation margin for example of ±10% or of other appropriate value that can be chosen according to practical application or design requirements.

In an embodiment, the second bias voltage Vbs2 may be derived from the first voltage Vtop that is applied to the first terminal 101A of the integrated resistive element 400 with a second scale-down coefficient K2, for example, expressed by Vbs2=K2*(Vtop−Vs)+Vs when taking the sensing voltage Vs at the sensing terminal 101S as a reference potential, wherein 0<K2<1. In an embodiment, the second scale-down coefficient K2 may be in a range from ⅓ to ⅔. In an embodiment, the second scale-down coefficient K2 may be substantially set to be ½ with a predetermined deviation margin for example of ±10% or of other appropriate value that may depend on practical application or design requirements.

Now referring to the partial cross-sectional view in the exemple of FIG. 5, the semiconductor substrate 103 includes an initial substrate layer 1031 of the first conductivity type, e.g., P type and an epitaxial layer 1032 of the first conductivity type formed atop the initial substrate layer 1031. The epitaxial layer 1032 may have a lower dopant concentration than the initial substrate layer 1031 in an example and is illustrated with a P-layer in FIG. 5. In the example of FIG. 5, each one of the first set of resistive segments 101_1, 101_2, 101_3 is formed atop the first well 102_1 while each one of the second set of resistive segments 101_4, 101_5, . . . , 101_N is formed atop the second well 102_2. In the cross-sectional view of FIG. 5, the observable resistive segment 101_N is illustrated out as an example to help understand the embodiments. In an embodiment, each one of the plurality of resistive segments 101_1, 101_2, . . . , 101_N may include a poly-silicon segment.

In an embodiment, each one of the plurality of resistive segments 101_1, 101_2, . . . , 101_N may be electrically coupled to one of the plurality of conductive connecting segments 101L at a first end (e.g., the left side end of the resistive segment 101_N in FIG. 5 is coupled to the one conductive connecting segment 101L at the left side) and to another one of the plurality of conductive connecting segments 101L at a second end (e.g., the right side end of the resistive segment 101_N in FIG. 5 is coupled to another one conductive connecting segment 101L at the right side). The plurality of resistive segments 101_1, 101_2, . . . , 101_N may be electrically coupled to the plurality of conductive connecting segments 101L through for example a plurality of interlayer routing elements 403 that are formed in a first ILD 405 disposed between the substrate 103 and the first conductive routing layer 401. The plurality of interlayer routing elements 403 may include vias VIA1 extending through the first ILD 405 and filled with electrically conductive materials such as metal and/or metal alloy etc., similarly as already described with reference to the example of FIG. 1.

In an embodiment, still referring to FIG. 5, an insulation layer 406 may be formed in each one of the first well 102_1 and the second well 102_2 and disposed under the plurality of resistive segments 101_1, 101_2, . . . , 101_N. That is, the insulation layer 406 in the first well 102_1 is disposed under the first set of resistive segments 101_1, . . . , 101_i while the insulation layer 406 in the second well 102_2 is disposed under the second set of resistive segments 101_(i+1), . . . , 101_N. The insulation layer 406 includes a silicon dioxide layer in an example. The insulation layer 406 includes a shallow trench isolation (STI) structure in another example.

In an embodiment, still referring to FIG. 5, a well contact region 402 is formed in each one of the first well 102_1 and the second well 102_2. The well contact regions 402 may have a higher dopant concentration than the first well 102_1 and the second well 102_2. The well contact region 402 of the first well 102_1 is coupled to the first well bus 102L1 while the well contact region 402 of the second well 102_2 is coupled to the second well bus 102L2 through for example a plurality of interlayer routing elements 404 that are formed in the first ILD 405 which is disposed between the substrate 103 and the first conductive routing layer 401. The plurality of interlayer routing elements 404 may include vias VIA1 extending through the first ILD 405 and filled with electrically conductive materials such as metal and/or metal alloy etc. The well contact regions 402 may help to form Ohmic contacts between the first well 102_1 and the interlayer routing elements 404, and between the second well 102_2 and the interlayer routing elements 404, and thus may be referred to as being “highly doped” or “heavily doped” by those skilled in the art (e.g., illustrated as an N+ region in FIG. 5).

In an embodiment, still referring to FIG. 5, according to application needs, the first well bus 102L1, the second well bus 102L2 and some of the plurality of conductive connecting segments 101L may be electrically coupled to corresponding conductive buses formed in a second conductive routing layer 410 disposed above the conductive routing layer 401 with a second ILD 408 disposed between the conductive routing layer 401 and the second conductive routing layer 410. In an exemplary embodiment, the second conductive routing layer 410 may include or be embodied as a second metal routing layer. The second ILD 408 may be formed atop the first ILD 405 and cover conductive elements (such as the first well bus 102L1, the second well bus 102L2 and the plurality of conductive connecting segments 101L) formed in the first conductive routing layer 401. It may alternatively be considered that the second ILD 408 is disposed between the first ILD 405 and the second conductive routing layer 410. In the examples of FIG. 4 and FIG. 5, the first well bus 102L1 in the first conductive routing layer 401 is electrically coupled to a corresponding bus 102T1 in the second conductive routing layer 410, the second well bus 102L2 in the first conductive routing layer 401 is electrically coupled to a corresponding bus 102T2 in the second conductive routing layer 410, the conductive connecting segments 101L in the first conductive routing layer 401 that are coupled to the ending one resistive segment 101_i in the first portion 101_R1 and the starting one resistive segment 101_(i+1) in the second portion 101_R2 are electrically coupled to a corresponding bus 101S in the second conductive routing layer 410, the conductive connecting segment 101L in the first conductive routing layer 401 that is coupled to the last one resistive segment 101_N of the plurality of resistive segments 101_1, . . . , 101_N is electrically coupled to a corresponding bus 101A in the second conductive routing layer 410, the conductive connecting segment 101L in the conductive routing layer 401 that is coupled to the first resistive segment 101_1 of the plurality of resistive segments 101_1, . . . , 101_N is electrically coupled to a corresponding bus 101B in the second conductive routing layer 410. One of ordinary skill in the art would understand that the buses 102T1, 102T2, 101S, 101A and 101B in the second conductive routing layer 410 as exemplarily illustrated and described with reference to FIG. 5 may respectively function as the first well terminal 102T1, the second well terminal 102T2, the sensing terminal 101S, the first terminal 101A and the second terminal 101B of the integrated resistive element 400. A plurality of interlayer routing elements 409 formed in the second ILD 408 may be used to fulfill the electrically coupling between buses (e.g., 102L1, 102L2 etc.) or connecting elements (e.g., 101L etc.) in the first conductive routing layer 401 and buses (e.g., 101A, 101B, 101S, 102T1, 102T2 etc.) in the second conductive routing layer 410 according to practical needs. For instance, the plurality of interlayer routing elements 409 may include vias VIA2 extending through the second ILD 408 and filled with electrically conductive materials such as metal and/or metal alloy etc.

In an embodiment, still referring to FIG. 5, shallow trench isolation structures 407 may be formed around each of the first well 102_1 and the second well 102_2. Alternatively speaking, a first shallow trench isolation structure 407 may be formed around (for example surrounding or circling around when inspected in corresponding plan view) the first well 102_1 in the substrate 103, and a second shallow trench isolation structure 407 may be formed around (for example surrounding or circling around) the second well 102_2 in the substrate 103. It can be easily understood by those of ordinary skill in the art that the first shallow trench isolation structure 407 may be formed, for example, surrounding or circling around the first well 102_1 when inspected in a corresponding plan view. The second shallow trench isolation structure 407 may be formed, for example, surrounding or circling around the second well 102_2 when inspected in a corresponding plan view. The “first” and “second” here are just used to help in differentiating the isolation structures 407 respectively formed around the first well 102_1 and the second well 102_2.

Now referring to the partial cross-sectional view in the example of FIG. 6, it should be understood by those of ordinary skill in the art that substantial descriptions made with reference to the example shown in FIG. 5 are applicable to the example of FIG. 6. Difference in one aspect may lie in that, in the example of FIG. 6, each one of the plurality of resistive segments 101_1, 101_2, . . . , 101_N may alternatively include a doped region of the first conductivity type (e.g., P type in FIG. 6) formed in the respective first well 102_1 and the second well 102_2 instead of a poly-silicon segment. That is, each one of the first set of resistive segments 101_1, ... 101_i includes a doped region of the first conductivity type formed in the first well 102_1, and each one of the second set of resistive segments 101_(i+1), . . . , 101_N includes a doped region of the first conductivity type formed in the second well 102_2. The doped region for implementing each one of the plurality of resistive segments 101_1, 101_2, . . . , 101_N has a dopant concentration higher than that of the first well 102_1 and the second well 102_2 and is illustrated as a P+ region in the example of FIG. 6. An ohmic contact can be formed between the doped regions 101_1, 101_2, . . . , 101_N and the interlayer routing elements 403. In another aspect, the insulation layer 406 may be omitted in the example of FIG. 6.

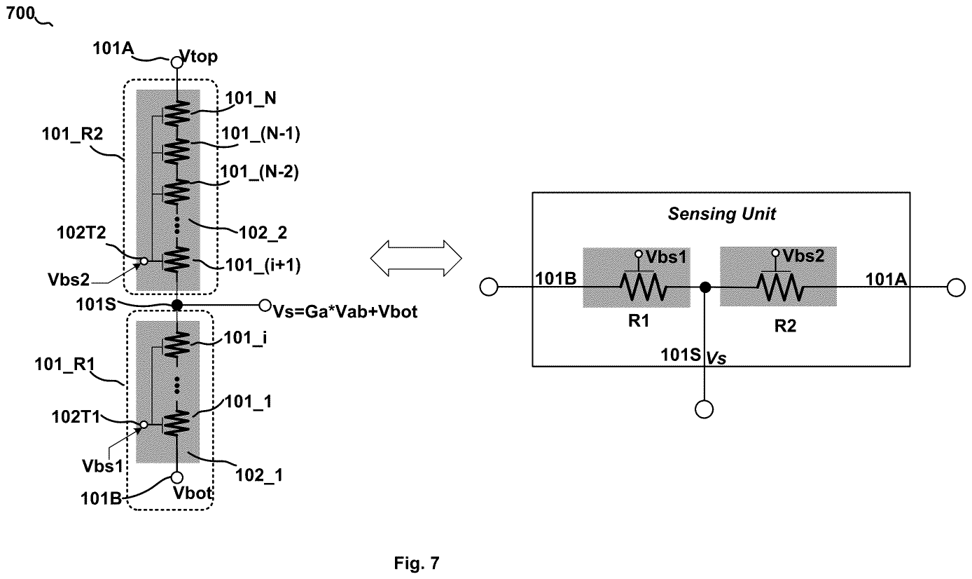

FIG. 7 illustrates an equivalent circuit schematic diagram 700 of the integrated resistive element 400 in accordance with an embodiment of the present invention when configured as the resistive sensing unit described with reference to the examples shown in FIG. 4, FIG. 5 and FIG. 6.

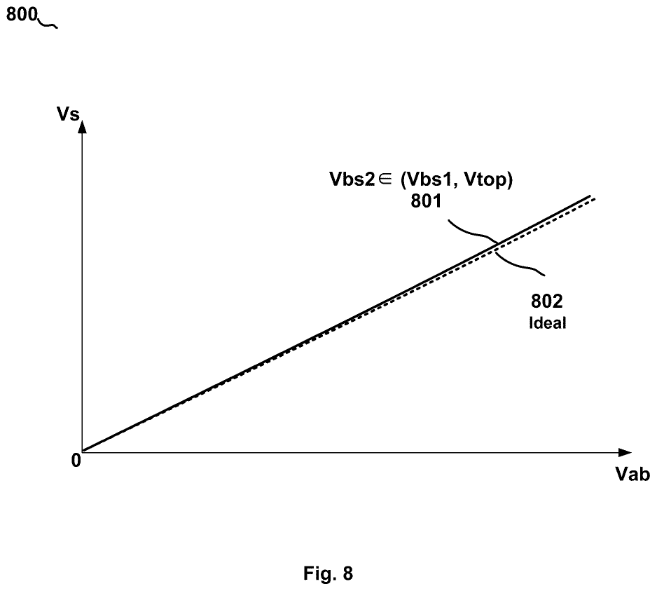

FIG. 8 illustrates a waveform diagram 800 illustrating a practical curve 801 of the sensing voltage Vs versus the voltage Vab across the integrated resistive element 400 when the second bias voltage Vbs2 applied to the second well 102_2 is substantially set between the first bias voltage Vbs1 and the first voltage Vtop (e.g., in a range from (Vab/3+Vbot) to (2*Vab/3+Vbot)) and a theoretically ideal curve 802 of the sensing voltage Vs versus the voltage Vab across the integrated resistive element 400. As can be seen from FIG. 8, the practical curve 801 substantially follows the ideal curve 802 with a low distortion, at least lower than that of the practical curve 301 shown in FIG. 3, which means that the sensing voltage Vs provided from the integrated resistive element 400 configured as the sensing unit in practical applications may have improved accuracy and linearity in following the change in the voltage Vab across the integrated resistive element 400 with reduced distortion. The more the second bias voltage Vbs2 being configured to be approaching to a middle value between the sensing voltage Vs and the first voltage Vtop that is [(Vtop−Vs)/2+Vs] or a middle value between the bias voltage Vbs1 and the first voltage Vtop that is [(Vtop−Vbs1)/2+Vbs1] or a middle value between the second voltage Vbot and the first voltage Vtop that is (Vab/2+Vbot), the lower the distortion between the practical curve 801 and the ideal curve 802 would become.

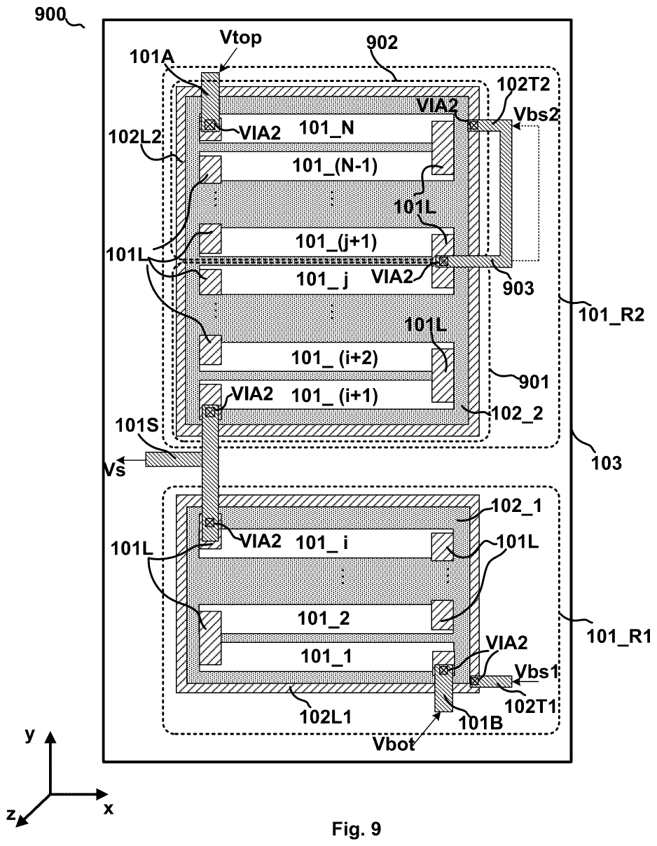

FIG. 9 illustrates a top plan view layout diagram of an integrated resistive element 900 in accordance with an embodiment of the present invention. Similar as described with reference to the integrated resistive element 400 of FIG. 4, the integrated resistive element 900 may be configured to form a resistive sensing unit to provide a sensing voltage Vs. Those skilled in the art would understand that substantial descriptions made to the integrated resistive element 400 with reference to FIG. 4 through FIG. 8 are applicable to the example of FIG. 9 and need not to be addressed again here for simplicity.

In the example shown in FIG. 9, the second well 102_2 may be self-biased from the second portion 101_R2 of the integrated resistive element 900. That is, the second bias voltage Vbs2 provided to the second well terminal 102T2 may be generated by reusing the second portion 101_R2 of the integrated resistive element 900. For instance, a terminal 903 between and connected to a third portion 901 and a fourth portion 902 of the second portion 101_R2 of the plurality of resistive segments 101_1, . . . 101_N may be configured to provide the second bias voltage Vbs2. And thus, the terminal 903 may also be referred to as a second well biasing terminal 903. The second well terminal 102T2 may be coupled to the second well biasing terminal 903. In the example of FIG. 9, the third portion 901 is illustratively shown to include a third set of resistive segments 101_(i+1), . . . , 101_j of the second portion 101_R2 and the fourth portion 902 is illustratively shown to include a fourth set of resistive segments 101_(j+1), . . . 101_N of the second portion 101_R2. Here, the variable j is an integer and is related to the number of the resistive segments that are included in the third portion 901 (i.e., the third set of resistive segments 101_(i+1), . . . , 101_j) and may have a value that can be set or predetermined according to the second bias voltage Vbs2 that is desired to be provided. For instance, the variable j may be set between (i+1) and N in the example shown in FIG. 9, and the number of resistive segments included in the third portion 901 (i.e., the third set of resistive segments 101_(i+1), . . . , 101_j) can be expressed by (j−i). In an example, the variable j may have a value set according to the second scale-down coefficient K2, the number i of the resistive segments included in the first portion 101_R1 (i.e., the first set of resistive segments 101_1, . . . , 101_i), and the total number N of the plurality of resistive segments 101_1, . . . 101_N included in the integrated resistive element 900. In an embodiment, the variable j may satisfy an expression of K2=(j−i)/(N−i) for the example of FIG. 9. The third portion 901 including the third set of resistive segments 101_(i+1), . . . , 101_j has a third resistance R3 depending on the number (j−i) of resistive segments included in the third portion 901, the fourth portion 902 including the fourth set of resistive segments 101_(j+1), . . . 101_N has a fourth resistance R4 depending on the number (N−j) of resistive segments included in the fourth portion 902. According to the exemplary embodiment of FIG. 9, the second well biasing terminal 903 is electrically coupled to a starting one resistive segment (e.g., the one labeled with 101_(j+1) in the example of FIG. 9) in the fourth portion 902 including the fourth set of resistive segments 101_(j+1), . . . 101_N and to an ending one resistive segment (e.g., the one labeled with 101_j in the example of FIG. 9) in the third portion 901 including the third set of resistive segments 101_(i+1), . . . , 101_j, for example, through one or more of the interlayer routing elements 409 such as interlayer vias VIA2 filled with electrically conductive materials (please refer to FIG. 5 and FIG. 6 in combination for better understanding) formed in the second ILD 408, a conductive connecting segment 101L in the first conductive routing layer 401, and one or more of the interlayer routing elements 403 such as interlayer vias VIA1 filled with electrically conductive materials formed in the first ILD 405 disposed between the first conductive routing layer 401 and the substrate 103. For this situation, the second bias voltage Vbs2 may be expressed by Vbs2=(Vtop−Vs)*R3/(R3+R4)+Vs=(Vtop−Vs)*R3/R2+Vs. In an example, for embodiments where the sensing voltage Vs is relatively low (e.g., lower than Vab/3+Vbot, that is Vs<Vab/3+Vbot) in comparison with the voltage Vab across the integrated resistive element 900, the second bias voltage Vbs2 may substantially be expressed as Vbs2≈Vab*R3/(R3+R4)=Vab*R3/R2. In an example, for embodiments where the sensing voltage Vs is relatively low and the second terminal 101B of the integrated resistive element 900 is connected to the ground GND having the ground voltage potential, the second bias voltage Vbs2 for the self-biased configuration shown in FIG. 9 may substantially be expressed by Vbs2≈Vtop*R3/(R3+R4)=Vtop*R3/R2.

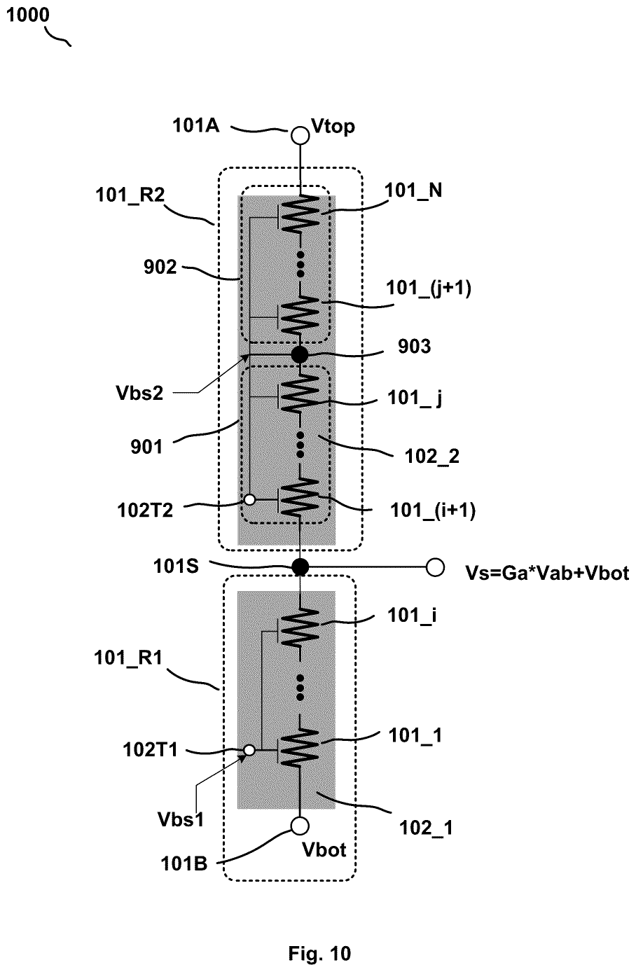

FIG. 10 illustrates an equivalent circuit schematic diagram 1000 of the integrated resistive element 900 in accordance with an embodiment of the present invention when configured as the resistive sensing unit described with reference to the example shown in FIG. 9. In the example of FIG. 10, the second well 102_2 is shown to be configured as self-biased from the second portion 101_R2.

In an embodiment, the first well 102_1 may be configured as either biased from the sensing voltage Vs for instance by connecting the first well terminal 102T1 to the sensing terminal 101S or from the second voltage Vbot that is applied to the second terminal 101B of the integrated resistive element 900 for instance by connecting the first well terminal 102T1 to the second terminal 101B.

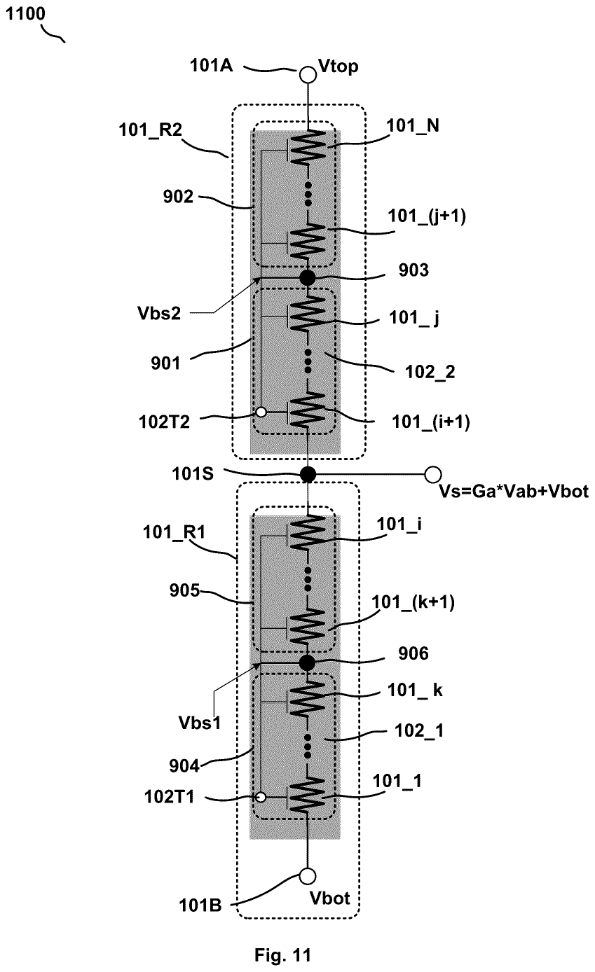

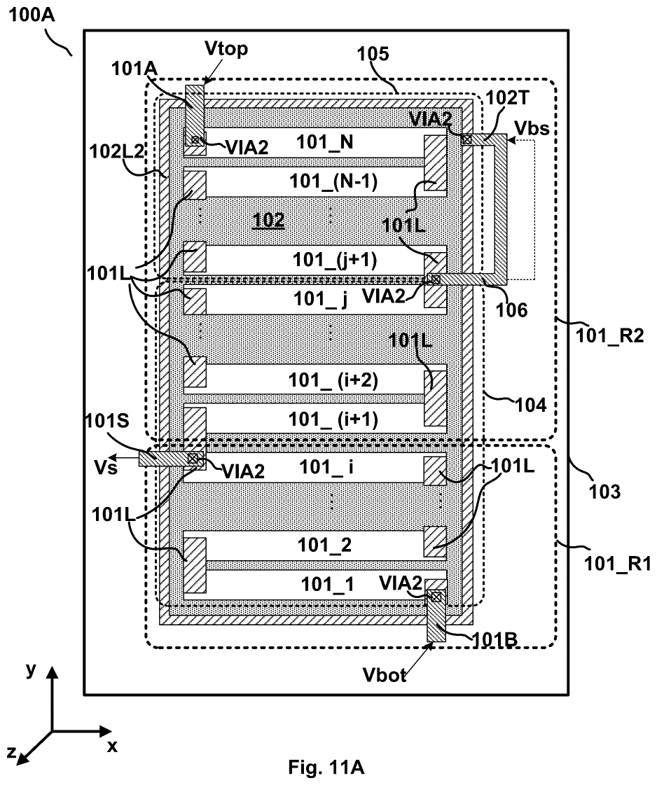

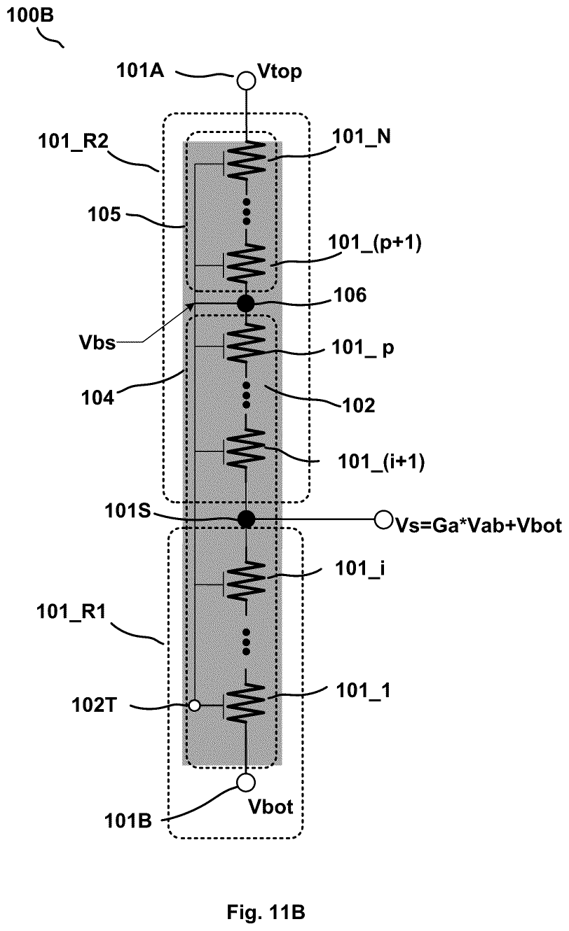

Those skilled in the art would understand that, in an alternative embodiment, the first well 102_1 may be self-biased from the first portion 101_R1 in an analogous manner as the second well 102_2 is self-biased, and thus details of configuring the first well 102_1 to be self-biased from the first portion 101_R1 can be well appreciated by persons of ordinary skill in the art by reading the descriptions above made for configuring the second well 102_2 to be self-biased from the second portion 101_R2 with reference to the exemplary illustration in FIG. 9 and will not need to be addressed here for simplicity. FIG. 11 illustrates an equivalent circuit schematic diagram 1100 of the integrated resistive element 900 in accordance with such an alternative embodiment of the present invention when configured as the resistive sensing unit. In the example of FIG. 11, the first well 102_1 is shown to be configured as self-biased from the first portion 101_R1 and the second well 102_2 is shown to be configured as self-biased from the second portion 101_R2. For instance, in an exemplary embodiment which could be understood by those of ordinary skill in the art in an analogous manner as illustrated in the example of FIG. 9 in conjunction with the schematic illustration in FIG. 11, a first well biasing terminal 906 disposed between and connected to a fifth portion 904 and a sixth portion 905 of the first portion 101_R1 of the plurality of resistive segments 101_1, . . . 101_N may be configured to provide the first bias voltage Vbs1. The first well terminal 102T1 may be coupled to the first well biasing terminal 906. In an example, the fifth portion 904 may include a fifth set of resistive segments (e.g., 101_1, . . . , 101_k) of the first portion 101_R1 and the sixth portion 905 may include a sixth set of resistive segments (e.g., 101_(k+1), . . . 101_i) of the first portion 101_R1. The variable k is an integer and is related to the number of the resistive segments that are included in the fifth portion 904 (i.e., the fifth set of resistive segments 101_1, . . . , 101_k) and may have a value that can be set or predetermined according to the first bias voltage Vbs1 that is desired to be provided. For instance, the variable k may be set between 1 and i referring to the example shown in FIG. 11, and the number of resistive segments included in the fifth portion 904 (i.e., the fifth set of resistive segments 101_1, . . . , 101_k) can be expressed by k. In an example, the variable k may have a value set according to the first scale-down coefficient K1. In an example, the variable k may satisfy an expression of K1=k/i. The first well biasing terminal 906 may be electrically coupled to a starting one resistive segment (e.g., 101_(k+1)) in the sixth portion 905 including the sixth set of resistive segments 101_(k+1), . . . 101_i and to an ending one resistive segment (e.g., 101_k) in the fifth portion 904 including the fifth set of resistive segments 101_1, . . . , 101_k.

Those skilled in the art would further understand that the well 102 of the integrated resistive element 100 may be self-biased from the integrated resistive element in an analogous manner as the first well 102_1 or the second well 102_2 is self-biased. For instance, FIG. 11A illustrates a top plan view layout diagram of an integrated resistive element 100A in accordance with an exemplary embodiment of the present invention. The integrated resistive element 100A may be considered as a variant developed based on the integrated resistive element 100 of FIG. 1 by further configuring the well 102 to be self-biased and with the total number of the plurality of resistive segments included in the integrated resistive element 100A extended to be more generically indicated by the variable N. FIG. 11B illustrates an equivalent circuit schematic diagram 100B of the integrated resistive element 100A in accordance with such an exemplary embodiment of the present invention when configured as the resistive sensing unit. In the examples of FIG. 11A and FIG. 11B, the well 102 of the integrated resistive element 100A is shown to be configured as self-biased from the integrated resistive element 100A itself. A well biasing terminal 106 disposed between and connected to a well-bias first portion 104 and a well-bias second portion 105 of the plurality of resistive segments 101_1, . . . 101_N may be configured to provide the bias voltage Vbs. The well terminal 102T may be coupled to the well biasing terminal 106. In an example, the well-bias first portion 104 may include a well-bias first set of resistive segments (e.g., 101_1, . . . , 101_p) of the plurality of resistive segments 101_1, . . . 101_N and the well-bias second portion 105 may include a well-bias second set of resistive segments (e.g., 101_(p+1), . . . , 101_N) of the plurality of resistive segments 101_1, . . . 101_N. The variable p is an integer and is related to the number of the resistive segments that are included in the well-bias first portion 104 (i.e., the well-bias first set of resistive segments 101_1, . . . , 101_p) and may have a value that can be set or predetermined according to the bias voltage Vbs that is desired to be provided. The well biasing terminal 106 may be electrically coupled to a starting one resistive segment (e.g., 101_(p+1)) in the well-bias second portion 105 including the well-bias second set of resistive segments 101_(p+1), . . . , 101_N and to an ending one resistive segment (e.g., 101_p) in the well-bias first portion 104 including the well-bias first set of resistive segments 101_1, . . . , 101_p.

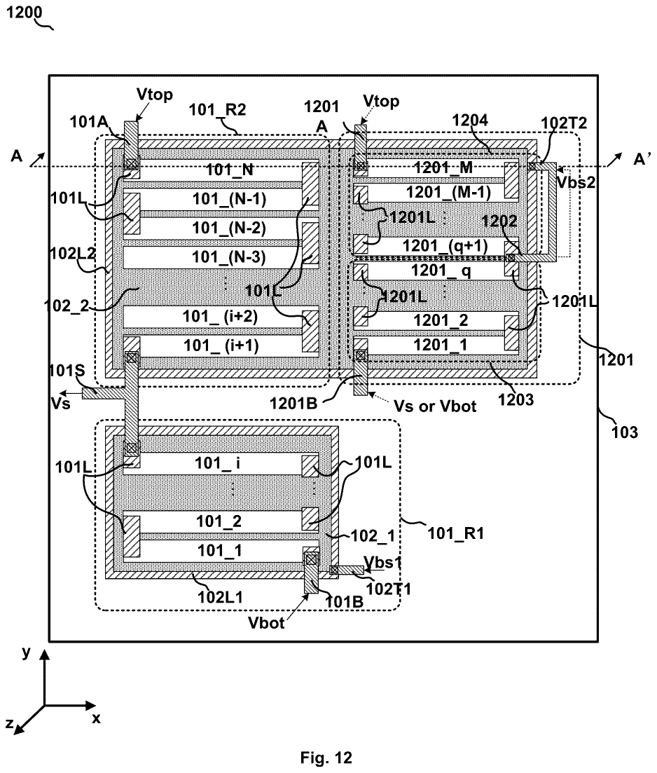

FIG. 12 illustrates a top plan view layout diagram of an integrated resistive element 1200 in accordance with an embodiment of the present invention. Similar as described with reference to the integrated resistive element 400 of FIG. 4, the integrated resistive element 1200 may be configured to form a resistive sensing unit to provide a sensing voltage Vs. Those skilled in the art would understand that substantial descriptions made with reference to the integrated resistive element 400 with reference to FIG. 4 through FIG. 8 are applicable to the example of FIG. 12 and need not to be addressed again here for simplicity.

In the example shown in FIG. 12, the second well 102_2 may be biased from a second well bias circuit 1201. The second well bias circuit 1201 may be configured to provide the second bias voltage Vbs2. The second well terminal 102T2 of the second well 102_2 may be electrically coupled to the second well bias circuit 1201 to receive the second bias voltage Vbs2. In an embodiment, the second well bias circuit 1201 may have a first terminal 1201A that is adapted to receive a first input signal, a second terminal 1201B that is adapted to receive a second input signal, and a third terminal 1202 that is adapted to provide the second bias voltage Vbs2. The second well bias circuit 1201 may be configured to provide the second bias voltage Vbs2 at the third terminal 1202 based on the first input signal and the second input signal. In an embodiment, the first input signal may be proportional to the first voltage Vtop that is provided to the first terminal 101A of the integrated resistive element 1200. In an embodiment, the second input signal may be proportional to the sensing voltage Vs or the second voltage Vbot that is provided to the second terminal 101B of the integrated resistive element 1200 or may be set to the reference ground potential.

In an embodiment, the first terminal of the second well bias circuit 1201 may be electrically connected to the first terminal 101A of the integrated resistive element 1200. In an embodiment, the first terminal 1201A of the second well bias circuit 1201 may be configured to receive the first voltage Vtop which is provided to the first terminal 101A of the integrated resistive element 1200. In an embodiment, the second terminal 1201B of the second well bias circuit 1201 may be electrically connected to the sensing terminal 101S or the second terminal 101B of the integrated resistive element 1200. In an embodiment, the second terminal 1201B of the second well bias circuit 1201 may be configured to receive the sensing voltage Vs or the second voltage Vbot which is provided to the second terminal 101B of the integrated resistive element 1200. In an embodiment, the second terminal 1201B of the second well bias circuit 1201 may be electrically connected to the ground GND having the ground voltage potential.

In the example of FIG. 12, the second well bias circuit 1201 may be formed in or on the second well 102_2 and includes a second plurality of resistive segments 1201_1, 1201_2, . . . , 1201_M. A total number of the second plurality of resistive segments 1201_1, 1201_2, . . . , 1201_M that the second well bias circuit 1201 includes is more generically represented by a variable M which is an integer greater than 1 and has a value that can be chosen or designed according to practical application and/or design requirements. The second plurality of (e.g., M) resistive segments 1201_1, . . . , 1201_M may be electrically coupled with each other by a second plurality of conductive connecting segments 1201L formed in the first conductive routing layer 401 of the integrated resistive element 1200. For this situation, the second well bus 102L2 may run surrounding the second set of conductive connecting segments among the plurality of conductive connecting segments 101L and the second plurality of conductive connecting segments 1201L when inspected in a plan view (i.e., from the x-y plane view) according to an exemplary embodiment as shown in FIG. 12. In an embodiment, the second plurality of (e.g., M) resistive segments 1201_1, . . . , 1201_M may substantially be identical to each other in perspectives of a geometry shape and/or a geometry size. That is, each one of the second plurality of (e.g., M) resistive segments 1201_1, . . . , 1201_M may have a shape and/or a size that are substantially identical to those of each one of the rest of the second plurality of resistive segments 1201_1, . . . , 1201_M, for instance, with a mismatching margin of within ±2% in an embodiment. In this fashion, it can be well understood by those of ordinary skill in the art that the second plurality of (e.g., M) resistive segments 1201_1, . . . , 1201_M have substantially identical resistance to each other. That is, each one of the second plurality of (e.g., M) resistive segments 1201_1, . . . , 1201_M may have a resistance that is substantially identical to a resistance of each one of the rests of the second plurality of (e.g., M) resistive segments 1201_1, . . . , 1201_M. The second plurality of (e.g., M) resistive segments 1201_1, . . . , 1201_M may be divided to include a second-well-bias first portion 1203 and a second-well-bias second portion 1204. The third terminal 1202 of the second well bias circuit 1201 is disposed between and connected to the second-well-bias first portion 1203 and the second-well-bias second portion 1204 of the second plurality of (e.g., M) resistive segments 1201_1, . . . , 1201_M and is configured to provide the second bias voltage Vbs2 to bias the second well 102_2. The second well terminal 102T2 may be coupled to the third terminal 1202 of the second well bias circuit 1201.

In the example of FIG. 12, the second-well-bias first portion 1203 is illustratively shown to include a first set of resistive segments 1201_1, . . . , 1201_q of the second plurality of (e.g., M) resistive segments 1201_1, . . . , 1201_M and the second-well-bias second portion 1204 is illustratively shown to include a second set of resistive segments 1201_(q+1), . . . , 1201_M of the second plurality of (e.g., M) resistive segments 1201_1, . . . , 1201_M. Here, the variable q is an integer and is indicative of the number of the resistive segments 1201_1, . . . , 1201_q that are included in the second-well-bias first portion 1203 and may have a value that can be set or predetermined according to the second bias voltage Vbs2 that is desired to be provided. For instance, the variable q may be set between 1 and M in the example shown in FIG. 12. In an example, the variable q may have a value set according to the second scale-down coefficient K2 and the total number M of the second plurality of resistive segments 1201_1, . . . 1201_M included in the second well bias circuit 1201. In an embodiment, the variable q may satisfy an expression of K2=q/M for the example of FIG. 12. The second-well-bias first portion 1203 including the first set of resistive segments 1201_1, . . . , 1201_q of the second plurality of (e.g., M) resistive segments 1201_1, . . . , 1201_M has a fifth resistance R5 depending on the number q of the resistive segments 1201_1, . . . , 1201_q that are included in the second-well-bias first portion 1203, the second-well-bias second portion 1204 including the second set of resistive segments 1201_(q+1), . . . , 1201_M of the second plurality of (e.g., M) resistive segments 1201_1, . . . , 1201_M has a sixth resistance R6 depending on the number (M−q) of resistive segments 1201_(q+1), . . . , 1201_M that are included in the second-well-bias second portion 1204. For this situation, the second bias voltage Vbs2 may be expressed by Vbs2=(Vtop−Vs)*R5/(R5+R6)+Vs. In an example, for embodiments where the sensing voltage Vs is relatively low (e.g., lower than Vab/3, that is Vs<Vab/3) in comparison with the voltage Vab across the integrated resistive element 1200, the second bias voltage Vbs2 may substantially be expressed as Vbs2≈Vab*R5/(R5+R6)+Vbot. In an example, for embodiments where the sensing voltage Vs is relatively low and the second terminal 101B of the integrated resistive element 1200 is connected to the ground GND having the ground voltage potential, the second bias voltage Vbs2 for the configuration shown in FIG. 12 may substantially be expressed by Vbs2≈Vtop*R5/(R5+R6).

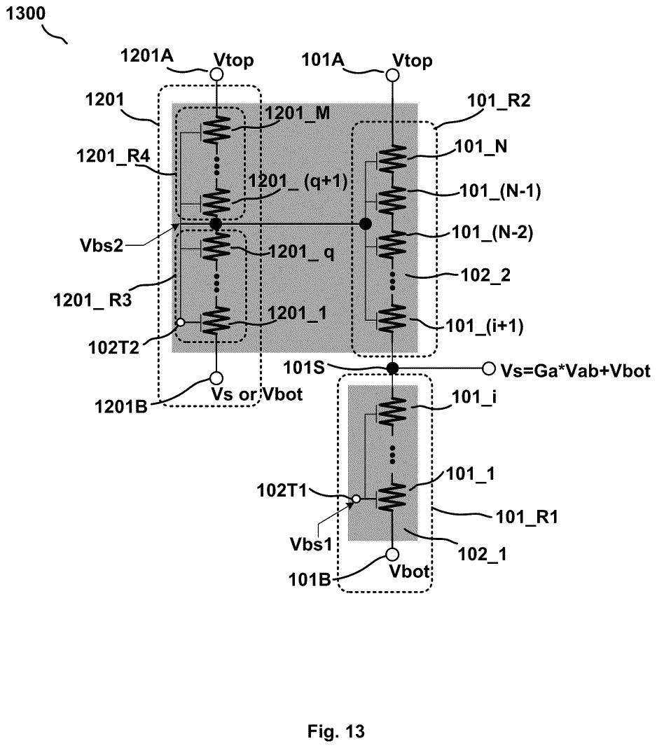

FIG. 13 illustrates an equivalent circuit schematic diagram 1300 of the integrated resistive element 1200 in accordance with an embodiment of the present invention when configured as the resistive sensing unit described with reference to the example shown in FIG. 12. In the example of FIG. 13, the second well 102_2 is shown to be configured as biased from the second well bias circuit 1201.

In an embodiment, the first well 102_1 may be configured as either biased from the sensing voltage Vs for instance by connecting the first well terminal 102T1 to the sensing terminal 101S or from the second voltage Vbot that is applied to the second terminal 101B of the integrated resistive element 1200 for instance by connecting the first well terminal 102T1 to the second terminal 101B.

Those skilled in the art would understand that, in an alternative embodiment, the first well 102_1 may be biased from a first well bias circuit in an analogous manner as the second well 102_2 is biased from the second well bias circuit 1201. The first well bias circuit may be configured to provide the first bias voltage in an analogous manner as the second well bias circuit 1201 is configured to provide the second bias voltage Vbs2. And thus, details of configuring the first well 102_1 to be biased from the first well bias circuit can be well appreciated by persons of ordinary skill in the art by reading the descriptions above made for configuring the second well 102_2 to be biased from the second well bias circuit 1201 and will not need to be addressed in detail here for simplicity. For instance, in an analogous manner, the first well bias circuit may have a first terminal that is adapted to receive a third input signal, a second terminal that is adapted to receive a fourth input signal, and a third terminal that is adapted to provide the first bias voltage Vbs1 based on the third input signal and the fourth input signal. In an embodiment, the first terminal of the first well bias circuit may be electrically connected to the sensing terminal 101S of the integrated resistive element 1200 to receive the sensing voltage Vs. The second terminal of the first well bias circuit may be electrically connected to the second terminal 101B of the integrated resistive element 1200 to receive the second voltage Vbot which is provided to the second terminal 101B. The first well terminal 102T1 may be coupled to the third terminal of the first well bias circuit. In an exemplary embodiment which could be understood by those of ordinary skill in the art in an analogous manner as illustrated in the example of FIG. 12, the first well bias circuit may be formed in or on the first well 102_1 and includes a third plurality of resistive segments. A total number of the third plurality of resistive segments that the first well bias circuit includes may be more generically represented by a variable which is an integer greater than 1 and has a value that can be chosen or designed according to practical application and/or design requirements. The third plurality of resistive segments may be electrically coupled with each other by a third plurality of conductive connecting segments formed in the first conductive routing layer 401 of the integrated resistive element 1200. For this situation, the first well bus 102L1 may run surrounding the first set of conductive connecting segments among the plurality of conductive connecting segments 101L and the third plurality of conductive connecting segments when inspected in a plan view (i.e., from the x-y plane view). In an embodiment, the third plurality of resistive segments may substantially be identical to each other in perspectives of a geometry shape and/or a geometry size and/or a resistance, for instance, with a mismatching margin of within ±2% in an embodiment. The third plurality of resistive segments may be divided to include a first-well-bias first portion and a first-well-bias second portion. The third terminal of the first well bias circuit is disposed between and connected to the first-well-bias first portion and the first-well-bias second portion of the third plurality of resistive segments and is configured to provide the first bias voltage Vbs1 to bias the first well 102_1.

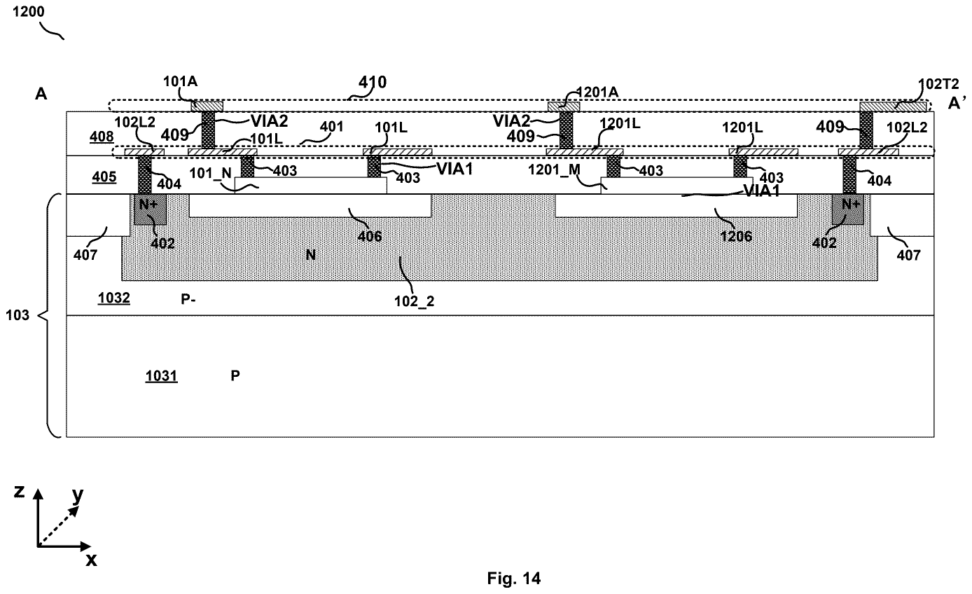

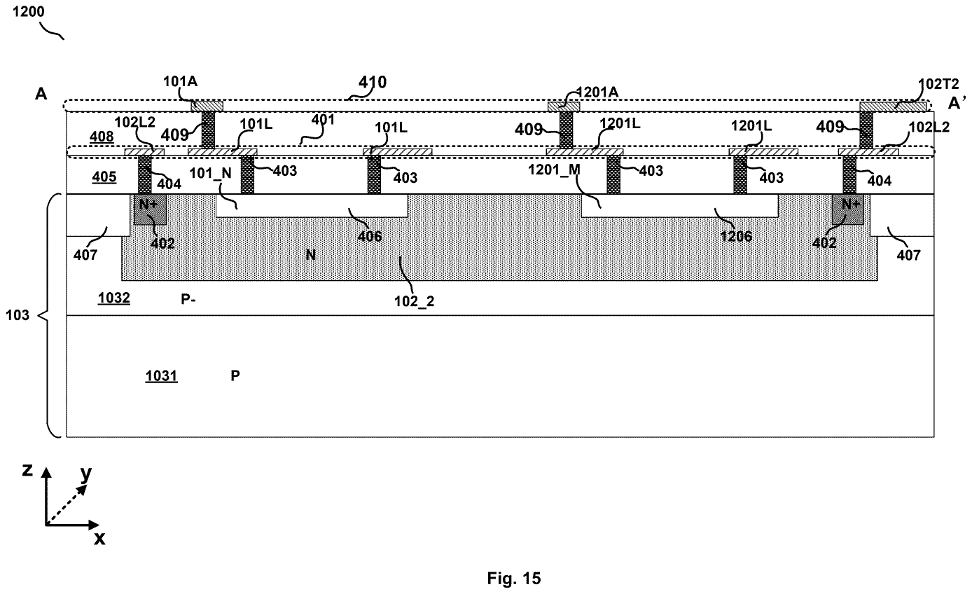

FIG. 14 illustrates a partial cross-sectional view of the integrated resistive element 1200 in accordance with an embodiment of the present invention. FIG. 15 illustrates a partial cross-sectional view of the integrated resistive element 1200 in accordance with an alternative embodiment of the present invention. It may be understood that the illustrative cross-sectional views of FIG. 14 and FIG. 15 may be considered as taken along the cutting line A-A′ in the top plan view of FIG. 12 with a cutting plane parallel to the x-z plane defined by the x and z axis.

As can obviously be understood by those of ordinary skill in the art that descriptions to the plurality of resistive segments 101_1, . . . , 101_N made with reference to FIG. 4 to FIG. 6 are applicable to the examples of FIG. 12, FIG. 14 and FIG. 15.

In the example of FIG. 14, each one of the second plurality of resistive segments 1201_1, . . . , 1201_M of the second well bias circuit 1201 is formed atop the second well 102_2. In the cross-sectional view of FIG. 14, the observable resistive segment 1201_M is illustrated out as an example to help understand the embodiment. In an embodiment, each one of the second plurality of resistive segments 1201_1, . . . , 1201_M of the second well bias circuit 1201 may include a poly-silicon segment. In an embodiment, each one of the second plurality of resistive segments 1201_1, . . . , 1201_M may be electrically coupled to one of the second plurality of conductive connecting segments 1201L at a first end (e.g., the left side end of the resistive segment 1201_M in FIG. 14 is coupled to the one conductive connecting segment 1201L at the left side) and to another one of the second plurality of conductive connecting segments 1201L at a second end (e.g., the right side end of the resistive segment 1201_M in FIG. 14 is coupled to another one conductive connecting segment 1201L at the right side). The second plurality of resistive segments 1201_1, . . . , 1201_M may be electrically coupled to the second plurality of conductive connecting segments 1201L through for example a plurality of interlayer routing elements 403 that are formed in the first ILD 405. In an embodiment, an insulation layer 1206 may be formed in the second well 102_2 and disposed under the second plurality of resistive segments 1201_1, . . . , 1201_M. The insulation layer 1206 includes a silicon dioxide layer in an example. The insulation layer 1206 includes a shallow trench isolation (STI) structure in another example.

In the example of FIG. 15, it should be understood by those of ordinary skill in the art that substantial descriptions made with reference to the example shown in FIG. 14 are applicable to the example of FIG. 15. Difference in one aspect may lie in that, in the example of FIG. 15, each one of the second plurality of resistive segments 1201_1, . . . , 1201_M may alternatively include a doped region of the first conductivity type (e.g., P type in FIG. 15) formed in the second well 102_2 instead of a poly-silicon segment. That is, each one of the second plurality of resistive segments 1201_1, . . . , 1201_M includes a doped region of the first conductivity type formed in the second well 102_2. The doped region for implementing each one of the second plurality of resistive segments 1201_1, . . . , 1201_M has a dopant concentration higher than that of the second well 102_2 and is illustrated as a P+region in the example of FIG. 15. An ohmic contact can be formed between the doped regions 1201_1, . . . , 1201_M and the interlayer routing elements 403. In another aspect, the insulation layer 1206 may be omitted in the example of FIG. 15.

Those of ordinary skill in the art would understand that, in addition to the particular examples illustrated in FIG. 12 to FIG. 15, there are many alternative embodiments to implement the second well bias circuit for biasing the second well 102_2 and/or to implement the first well bias circuit for biasing the first well 102_1.

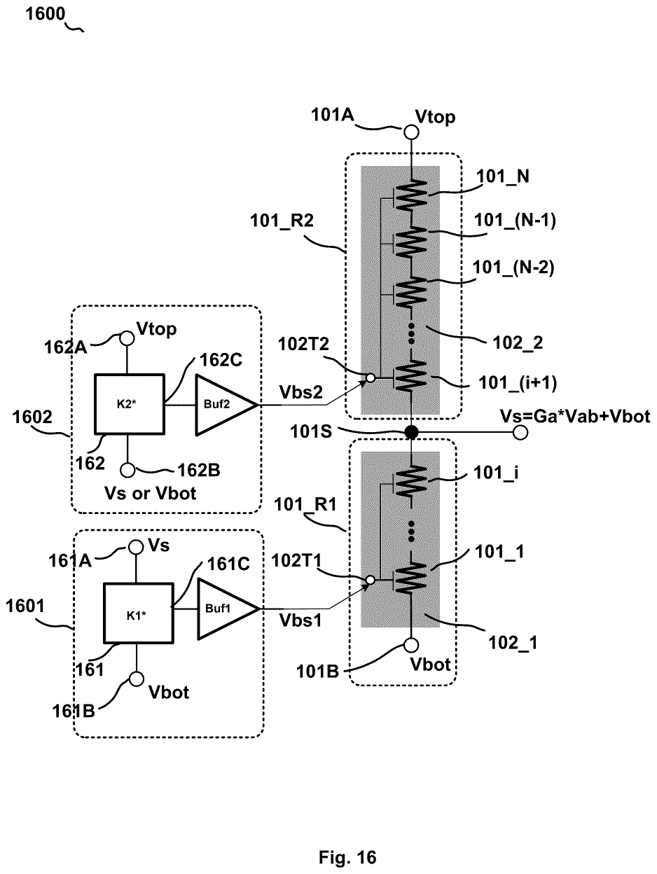

For instance, FIG. 16 illustrates an equivalent circuit schematic diagram 1600 of an integrated resistive element 1600 in accordance with an embodiment of the present invention when configured as a resistive sensing unit. It is obvious to persons of ordinary skill in the art that substantial descriptions made to the integrated resistive element 400 with reference to FIG. 4 through FIG. 8 are applicable to the example of FIG. 16 and need not to be addressed again here for simplicity.

Referring to the illustrative schematic diagram shown in FIG. 16, in an embodiment, the first well 102_1 may be configured to be biased from a first well bias circuit 1601 that is configured to provide the first bias voltage Vbs1. That is, the first well terminal 102T1 of the first well 102_1 may be electrically coupled to the first well bias circuit 1601 to receive the first bias voltage Vbs1. In an embodiment, the first well bias circuit 1601 may include a first voltage scaling circuit 161 having the first scale-down coefficient K1. The first voltage scaling circuit 161 may have a first terminal 161A, a second terminal 161B and a third terminal 161C, and may be configured to provide a first scaled voltage at the third terminal 161C based on signals received respectively at the first terminal 161A and the second terminal 161B. For example, the first scaled voltage may be proportional to a voltage difference between the signals received respectively at the first terminal 161A and the second terminal 161B with the first scale-down coefficient K1. In an embodiment, the first well bias circuit 1601 may further include a first buffer buf1 connected to the third terminal 161C of the first voltage scaling circuit 161. The first scaled voltage may be provided through the first buffer buf1 as the first bias voltage Vbs1.

In an embodiment, the second well 102_2 may be configured to be biased from a second well bias circuit 1602 that is configured to provide the second bias voltage Vbs2. That is, the second well terminal 102T2 of the second well 102_2 may be electrically coupled to the second well bias circuit 1602 to receive the second bias voltage Vbs2. In an embodiment, the second well bias circuit 1602 may include a second voltage scaling circuit 162 having the second scale-down coefficient K2. The second voltage scaling circuit 162 may have a first terminal 162A, a second terminal 162B and a third terminal 162C, and may be configured to provide a second scaled voltage at the third terminal 162C based on signals received respectively at the first terminal 162A and the second terminal 162B. For example, the second scaled voltage may be proportional to a voltage difference between the signals received respectively at the first terminal 162A and the second terminal 162B of the second voltage scaling circuit 162 with the second scale-down coefficient K2. In an embodiment, the second well bias circuit 1602 may further include a second buffer buf2 connected to the third terminal 162C of the second voltage scaling circuit 162. The second scaled voltage may be provided through the second buffer buf2 as the second bias voltage Vbs2.

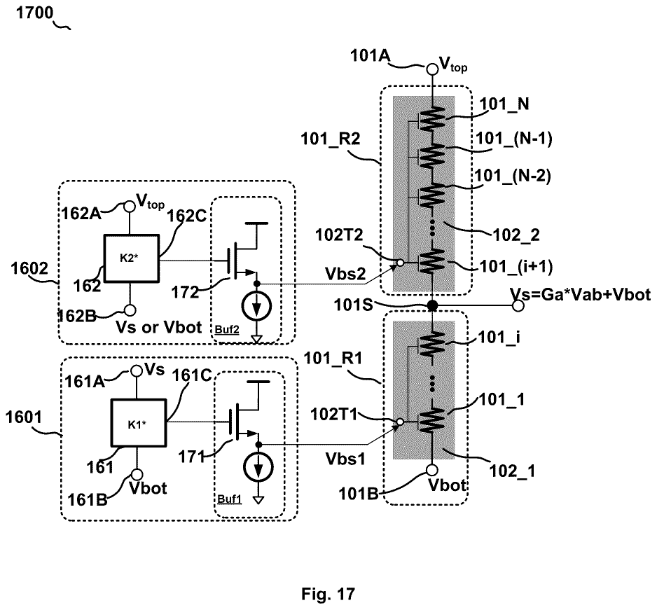

FIG. 17 illustrates an equivalent circuit schematic diagram 1700 of an integrated resistive element 1700 in accordance with an embodiment of the present invention when configured as a resistive sensing unit. Substantial descriptions made to the integrated resistive element 1600 with reference to FIG. 16 are applicable to the example of FIG. 17 and need not to be addressed again here for simplicity. In the example of FIG. 17, the first buffer buf1 is illustrated to include a first transistor 171 configured in a “source follower” configuration and the second buffer buf2 is illustrated to include a second transistor 172 configured in a “source follower” configuration. The first transistor 171 and the second transistor 172 may respectively comprise a MOSFET, for example.

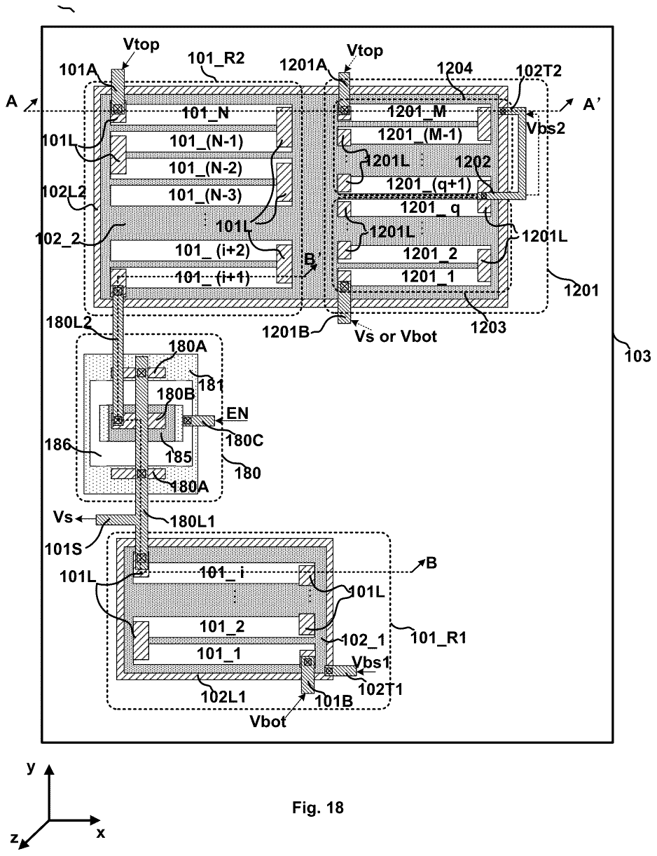

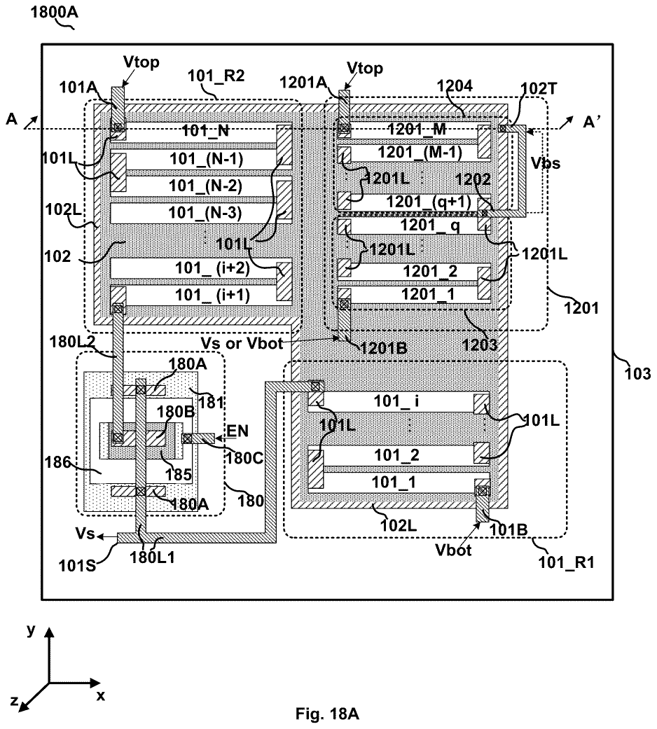

FIG. 18 illustrates a top plan view layout diagram of an integrated resistive element 1800 in accordance with an embodiment of the present invention. Similar as described with reference to the integrated resistive element 400 of FIG. 4, the integrated resistive element 1800 may be configured to form a resistive sensing unit to provide a sensing voltage Vs. Those skilled in the art would understand that substantial descriptions made with reference to the various integrated resistive elements in accordance with the exemplary embodiments disclosed above (such as the integrated resistive element 100 with reference to FIG. 1 through FIG. 2, the integrated resistive element 400 with reference to FIG. 4 through FIG. 8, the integrated resistive element 900 with reference to FIG. 9 through FIG. 11, the integrated resistive element 1200 with reference to FIG. 12 through FIG. 15, the integrated resistive element 1600 with reference to FIG. 16 and the integrated resistive element 1700 with reference to FIG. 17) are applicable to the example of FIG. 18 and need not to be addressed again here for simplicity. Compared with the various integrated resistive elements in accordance with the exemplary embodiments disclosed above, in one aspect, the integrated resistive element 1800 may further include a protection circuit 180. Although in the example of FIG. 18, it is illustratively shown that the integrated resistive element 1800 may be considered as a variant developed based on the integrated resistive element 1200 of FIG. 12 by further incorporating the protection circuit 180, one of ordinary skill in the art would understand that this is just to provide an example and to help better understand various embodiments of integrated resistive elements that include such a protection circuit 180 with the understanding that various other embodiments of the integrated resistive elements including such protection circuit 180 may be developed based on other exemplary embodiments of the integrated resistive elements (e.g., 100, 400, 900, 1600 or 1700) as disclosed above.

For instance, FIG. 18A illustrates a top plan view layout diagram of an integrated resistive element 1800A in accordance with another exemplary embodiment of the present invention. The integrated resistive element 1800A may be considered as a variant developed based on the integrated resistive element 100 of FIG. 1 by further incorporating the protection circuit 180 and with the total number of the plurality of resistive segments included in the integrated resistive element 1800A extended to be more generically indicated by the variable N. In addition, just to provide an example, the integrated resistive element 1800A may further include a well bias circuit that is configured to be operative to provide the bias voltage Vbs to bias the well 102. The well terminal 102T of the integrated resistive element 1800A may be electrically coupled to the well bias circuit to receive the bias voltage Vbs. For instance, in the example shown in FIG. 18A, the well bias circuit of the integrated resistive element 1800A may be embodied similarly as the second well bias circuit 1201 described with reference to the example of FIG. 12 with the second bias voltage Vbs2 generated by the second well bias circuit 1201 provided as the bias voltage Vbs to bias the well 102 of the integrated resistive element 1800A. For this situation, as an example, when the well bias circuit is implemented similarly as the second well bias circuit 1201 to include the second plurality of resistive segments 1201_1, 1201_2, . . . , 1201_M, the second plurality of resistive segments 1201_1, 1201_2, . . . , 1201_M may be formed in or on the well 102. In other embodiments, the well bias circuit of the integrated resistive element 1800A may be implemented with various other bias circuits that are operative to provide a bias voltage, for example, similarly as the first well bias circuit 1601 or the second well bias circuit 1602 as described with reference to FIG. 16 and FIG. 17, which is obvious and easy to understand by those of ordinary skill in the art.

The protection circuit 180 may be electrically coupled between the first portion 101_R1 and the second portion 101_R2 of the plurality of resistive segments 101_1, 101_2, . . . , 101_N, as illustratively shown in the example of the integrated resistive element 1800 of FIG. 18. In an embodiment, the protection circuit 180 may include a third well 181 that is formed in the substrate 103 and separated from the second well 102 (or separated from the first well 102_1 and the second well 102_2 for embodiments where the second well 102 is divided into multiple wells including the first well 102_1 and the second well 102_2). The third well 181 may be of the first conductivity type, for instance P type in the examples of FIG. 18 and FIG. 18A. In an embodiment, the protection circuit 180 is formed in the third well 181. The protection circuit 180 may have a protection first terminal 180A that is electrically coupled or connected to the first portion 101_R1 for example through a protection first connecting bus 180L1, a protection second terminal 180B that is electrically coupled or connected to the second portion 101_R2 for example through a protection second connecting bus 180L2, and a protection third terminal 180C that is configured as a protection control terminal. In an embodiment, the protection first terminal 180A and the protection second terminal 180B may be formed in the first conductive routing layer 401 of the integrated resistive element (e.g., 1800 or 1800A), the protection first connecting bus 180L1, the protection second connecting bus 180L2 and the protection third terminal 180C may be formed in the second conductive routing layer 410 of the integrated resistive element (e.g., 1800 or 1800A). The protection circuit 180 may be configured to be operable to enable or disable a path between the protection first terminal 180A and the protection second terminal 180B according to an electrical status of the protection control terminal 180C. The sensing terminal 101S may be disposed between the protection circuit 180 and the first portion 101_R1 and electrically coupled or connected to the protection first terminal 180A of the protection circuit 180 and the first portion 101_R1 in this example. Alternatively speaking, the sensing terminal 101S may be led out from the protection first terminal 180A of the protection circuit 180 in this example. The protection circuit 180 may be considered as electrically coupled between the sensing terminal 101S and the second portion 101_R2 of the plurality of resistive segments 101_1, 101_2, . . . , 101_N of the integrated resistive element 1800 with the sensing terminal 101S electrically connected to the first portion 101_R1. While the first portion 101_R1 (i.e., including the first set of the resistive segments 101_1, . . . , 101_i) of the plurality of resistive segments 101_1, 101_2, . . . , 101_N of the integrated resistive element 1800 is electrically coupled between the sensing terminal 101S and the second terminal 101B of the integrated resistive element 1800 or 1800A with the sensing terminal 101S electrically coupled to the protection circuit 180 (e.g., to the protection second terminal 180B of the protection circuit 180), the second portion 101_R2 (i.e., including the second set of the resistive segments 101_(i+1), . . . , 101_N) of the plurality of resistive segments 101_1, 101_2, . . . , 101_N of the integrated resistive element 1800 or 1800A is electrically coupled between the first terminal 101A and the protection circuit 180 (e.g., between the first terminal 101A of the integrated resistive element 1800 or 1800A and the protection second terminal 180B of the protection circuit 180) in this example. The sensing terminal 101S may be electrically coupled to an ending one resistive segment (e.g., the one labeled with 101_i in the example of FIG. 18 or FIG. 18A) in the first portion 101_R1 (i.e., including the first set of the resistive segments 101_1, . . . , 101_i) and to the protection first terminal 180A of the protection circuit 180 while a starting one resistive segment (e.g., the one labeled with 101_(i+1) in the example of FIG. 18 or FIG. 18A) in the second portion 101_R2 (i.e., including the second set of the resistive segments 101_(i+1), . . . , 101_N) may be electrically coupled to the protection second terminal 180B of the protection circuit 180 according to the embodiment of FIG. 18 or FIG. 18A.

The protection circuit 180 may advantageously help to protect other elements or circuitries that may be electrically coupled or connected to the sensing terminal 101S from being damaged when the voltage Vab across the integrated resistive element that includes the protection circuit 180 (such as the integrated resistive element 1800 of FIG. 18 or 1800A of FIG. 18A as an example) becomes too high in practical application, for instance higher than a maximum voltage withstanding capacity of the elements or circuitries that are connected to the sensing terminal 101S. For instance, in an embodiment, the maximum voltage withstanding capacity of the elements or circuitries that are connected to the sensing terminal 101S may be no greater than 5V while the voltage Vab across the integrated resistive element 1800 or 1800A may go as high as 20V even up to above 70V. The protection circuit 180 may have a breakdown voltage higher than a maximum voltage rating of the voltage Vab across the integrated resistive element 1800 or 1800A that may be applied on the integrated resistive element 1800 in practical applications. The protection circuit 180 may further be beneficial to reducing power consumption and power dissipation of the integrated resistive element that includes the protection circuit 180 (such as the integrated resistive element 1800 of FIG. 18 or 1800A of FIG. 18A as an example) or the sensing unit implemented with the integrated resistive element that includes the protection circuit 180 (e.g. the integrated resistive element 1800 or 1800A) in practical applications. These and other advantages may not be exhaustively addressed in the present disclosure since various advantages can be appreciated by those of ordinary skill in the art when reading the present disclosure.

In an embodiment, the protection circuit 180 may be configured to be operative to enable the path between the protection first terminal 180A and the protection second terminal 180B when the protection control terminal 180C is at a first electrical status, and to disable the path between the protection first terminal 180A and the protection second terminal 180B when the protection control terminal 180C is at a second electrical status. When the path between the protection first terminal 180A and the protection second terminal 180B is enabled, the path between the protection first terminal 180A and the protection second terminal 180B becomes electrically conductive and allows signal transmission between the protection first terminal 180A and the protection second terminal 180B, and thus electrically couples or connects the first portion 101_R1 and the sensing terminal 101S to the second portion 101_R2. When the path between the protection first terminal 180A and the protection second terminal 180B is disabled, the path between the protection first terminal 180A and the protection second terminal 180B becomes non-conductive and blocks signal transmission between the protection first terminal 180A and the protection second terminal 180B, and thus electrically decouples or disconnects the first portion 101_R1 and the sensing terminal 101S from the second portion 101_R2. That is, the protection circuit 180 may be configured to be operative to enable an electrical coupling or connection from the second portion 101_R2 to the sensing terminal 101S and the first portion 101_R1 when the protection control terminal 180C is at the first electrical status, and may further be configured to be operative to disable the electrical coupling or connection from the second portion 101_R2 to the sensing terminal 101S and the first portion 101_R1 when the protection control terminal 180C is at the second electrical status.

In an exemplary embodiment as illustrated in FIG. 18 or FIG. 18A, the protection circuit 180 includes a controllable transistor such as an asymmetric field effect transistor that may be selected from a variety of transistor devices including a double diffused metal oxide (“DMOS”), a junction field effect transistor (“JFET”), etc. The controllable transistor has a source terminal configured as the protection first terminal 180A, a drain terminal configured as the protection second terminal 180B and a gate terminal configured as the protection control terminal 180C. In the example of FIG. 18 or FIG. 18A, the protection circuit 180 is illustrated as to include a DMOS to help understand the embodiment. However, this is not intended to be limiting.

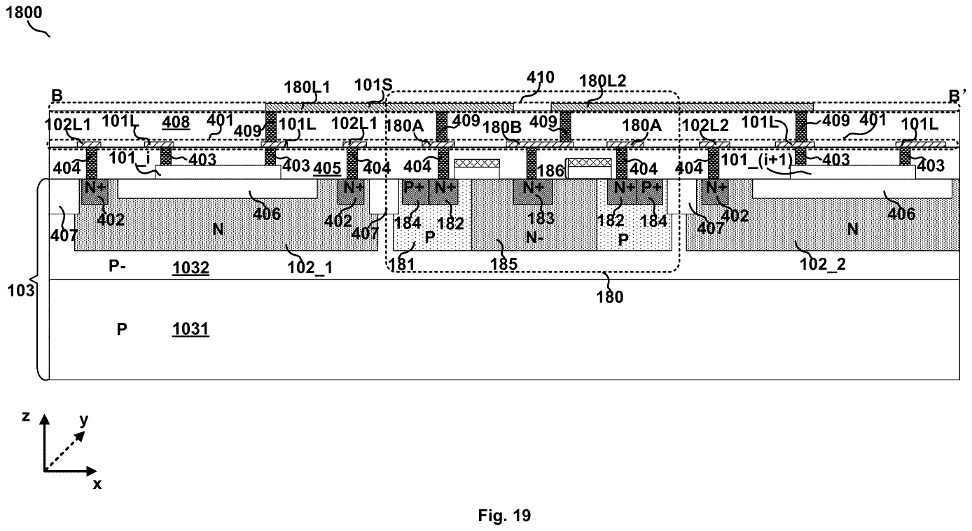

FIG. 19 illustrates a partial cross-sectional view of the integrated resistive element 1800 in accordance with an embodiment of the present invention. It may be understood that the illustrative cross-sectional view of FIG. 19 may be considered as taken along the cutting line B-B′ in the top plan view of FIG. 18. More details and operations of the integrated resistive element 1800 may be understood referring to FIG. 18 in conjunction with FIG. 19, FIG. 14 and/or FIG. 15. In the partial cross-sectional view shown in FIG. 19, the DMOS of the protection circuit 180 is exemplarily illustrated to include a source region 182 of the second conductivity type (e.g., shown as an N+ region) formed in the third well 181, a drain region 183 of the second conductivity type (e.g., shown as another N+ region) separated from the source region 182 and formed in a drift region 185 (e.g., shown as an N− region) of the second conductivity type having a lower dopant concentration than that of the drain region 183, and a gate region 186 formed atop the epitaxial layer 1032 and disposed between the source region 182 and the drain region 183. A body contact region 184 may be further formed next to the source region 182 and contacting with the source region 182 in the third well 181. In an embodiment, the protection first terminal 180A may be electrically coupled to the source region 182 for example through one or more of the interlayer routing elements 404 formed in the first ILD 405 and may further be electrically coupled to the protection first connecting bus 180L1 for example through one or more of the interlayer routing elements 409 formed in the second ILD 408. The protection first connecting bus 180L1 may be electrically coupled to the first portion 101_R1 (e.g., to the ending one resistive segment 101_i of the first portion 101_R1) through one or more of the interlayer routing elements 409 formed in the second ILD 408. The protection second terminal 180B may be electrically coupled to the drain region 183 for example through one or more of the interlayer routing elements 404 in the first ILD 405 and may further be electrically coupled to the protection second connecting bus 180L2 for example through one or more of the interlayer routing elements 409 formed in the second ILD 408. The protection second connecting bus 180L2 may be electrically coupled to the second portion 101_R2 (e.g., to the starting one resistive segment 101_(i+1) of the second portion 101_R2) through one or more of the interlayer routing elements 409 formed in the second ILD 408. The protection third terminal 180C may be electrically coupled to the gate region 186.

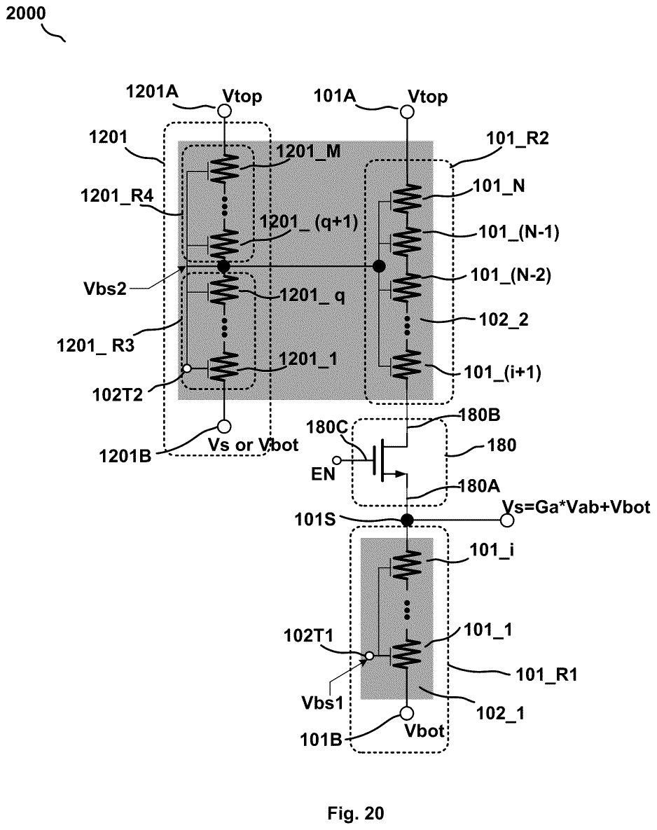

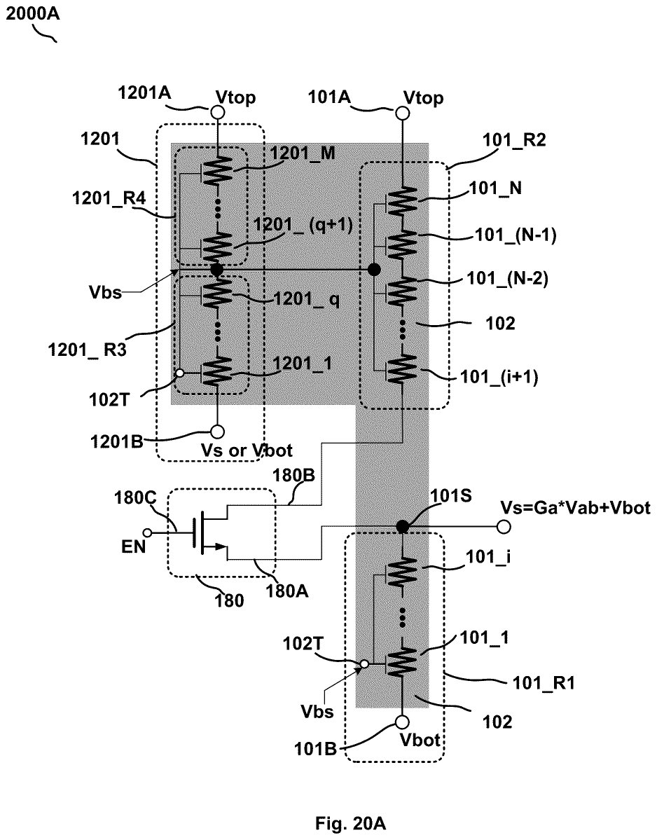

FIG. 20 illustrates an equivalent circuit schematic diagram 2000 of the integrated resistive element 1800 in accordance with an embodiment of the present invention when configured as the resistive sensing unit described with reference to the examples shown in FIG. 18 and FIG. 19. FIG. 20A illustrates an equivalent circuit schematic diagram 2000A of the integrated resistive element 1800A in accordance with an embodiment of the present invention when configured as the resistive sensing unit described with reference to the example shown in FIG. 18A.

The integrated resistive elements operative as the resistive sensing units according to various embodiments of the present disclosure may find a large variety of applications and may be used in various electronic apparatuses that require signal sensing.

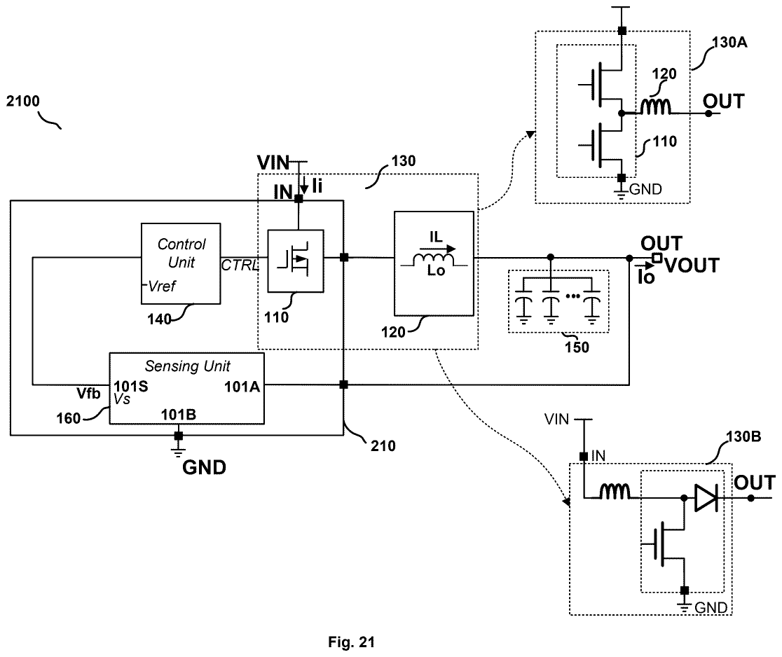

FIG. 21 illustrates a block diagram of an electronic apparatus including a power management apparatus 2100 in accordance with an embodiment of the present invention. The power management apparatus 2100 may be adapted to be used for sourcing power from a power source to a load. The power management apparatus 2100 may have an input terminal IN configured to be operative to receive an input power signal from a power source and an output terminal OUT configured to be operative to provide an output power signal. The power management apparatus 2100 may require signal sensing for controlling power transmission between the input terminal IN and the output terminal OUT or regulating the output power signal as will be described in more detail in the following. The power source may comprise a power supply such as a battery/battery pack or other circuit for providing power to another circuit. In the example of FIG. 21, the power source provides the input power signal to the power management apparatus 2100 in the form of an input voltage VIN which may be a DC voltage or an input current Ii. However, this is not to be limiting, power source that can provide an input power signal to the power management apparatus 2100 in other forms is applicable.

In an embodiment, the power management apparatus 2100 may include a power switching unit 110. The power switching unit 110 may be adapted to regulate energy or power transmitted from the input terminal IN to the output terminal OUT (or to the load) in response to control signal(s) (e.g. a control signal CTRL illustrated in the example of FIG. 21). In an embodiment, the power switching unit 110 may include at least one power switch such as a power transistor device that may be controllable to implement ON and OFF switching. In an embodiment, the power switching unit 110 may further include a driver to drive the at least one power switch in the power switching unit 110.

In accordance with an exemplary embodiment, the power switching unit 110 may be adapted to be configurable for controlling a switching of energy storage and energy release in an inductive energy storage device 120 based on the control signal(s) (such as the control signal CTRL illustrated in FIG. 21), thereby converting the input power signal (e.g., in the form of an input volage VIN and/or an input current Ii in FIG. 21) to the output power signal (e.g., in the form of an output voltage VOUT and/or an output current Io in FIG. 21). Generally, a period during which the power switching unit 110 may be configured to couple the inductive energy storage device 120 such that energy may be transferred from the input terminal IN to the inductive energy storage device 120 for energy storage may be referred to as an on time Ton (which can also be considered as an on time of the power switching unit 110 or may also be referred to as an on time of the power management apparatus 100), and a period during which the power switching unit 110 may be configured to couple the inductive energy storage device 120 such that energy may be transferred from the inductive energy storage device 120 to the output terminal OUT for energy release may be referred to as an off time Toff (which can also be considered as an off time of the power switching unit 110 or may also be referred to as an off time of the power management apparatus 100). The sum of the on time Ton and the off time Toff experienced every time a switching between the energy storage and the energy release in the inductive energy storage device 120 is completed may be referred to as an operating cycle or switching cycle Top of the power management apparatus 2100, and a ratio of the on time Ton to the sum of the on time Ton and the off time Toff in each operating cycle Top may be referred to as an on-duty ratio of the power switching unit 110 or a duty ratio of the power management apparatus 2100. The control signal(s) such as the control signal CTRL illustrated in FIG. 21 may be adapted to control the power switching unit 110 to implement switching between the energy storage and the energy release in the inductive energy storage device 120 and may be adapted to regulate the on time Ton and/or the off time Toff or the duty ratio or the switching cycle Top (or a switching frequency Fop=1/Top). In this fashion, the energy or power transmitted to the output terminal OUT in each switching cycle may be regulated. For instance, the output power signal in the form of the output voltage VOUT and/or the output current Io may be regulated.

In accordance with an exemplary embodiment, the power switching unit 110 may be configured to co-work with the inductive energy storage device 120 to implement a power conversion topology 130. The power conversion topology 130 may include any isolated or non-isolated synchronous or non-synchronous power conversion topology including but not limited to a DC to DC power conversion topology or an AC to DC power conversion topology or a DC to AC power conversion topology, etc. In an example, the power conversion topology 130 may include a synchronous non-isolated DC to DC power conversion topology, for instance, a DC to DC buck power conversion topology, or a DC to DC boost power conversion topology, or a DC to DC buck-boost power conversion topology. An exemplary DC to DC buck power conversion topology 130A is shown in FIG. 21 to provide an exemple. An exemplary DC to DC boost power conversion topology 130B is shown in FIG. 21 to provide another exemple.

In an embodiment, the power management apparatus 2100 may further include a control unit 140 to provide the control signal(s) for controlling the power switching unit 110. In an embodiment, the control unit 140 may be adapted to provide the control signal(s) to the power switching unit 110 based on information indicative of the input signal (e.g., information indicative of the input voltage VIN and/or the input current Ii), and/or information indicative of the output signal (e.g., information indicative of the output voltage VOUT and/or the output current Io) etc.

In an embodiment, the power management apparatus 2100 may further include a sensing unit 160. The sensing unit 160 may be configured to be operative to sense the output signal (e.g., the output voltage VOUT and/or the output current Io) in an embodiment to provide the information indicative of the output signal as shown in the example of FIG. 21. The sensing unit 160 may be implemented with any one of the integrated resistive elements that can be configured as a resistive sensing unit in accordance with various embodiments of the present invention as described with reference to FIG. 1 through FIG. 20A. In such an application example, the integrated resistive element that is used to implement the sensing unit 160 is configured to have its first terminal 101A operative to be electrically coupled to the output terminal OUT to receive the output signal, its second terminal 101B operative to be electrically connected to the reference ground GND, and its sensing terminal 101S operative to be configured to provide the sensing voltage Vs as a feedback signal Vfb that may be provided to the control unit 140 as the information indicative of the output signal. The power management apparatus 2100 having the sensing unit 160 implemented with an integrated resistive element as described with various embodiments of the present invention may in one aspect advantageously improve an accuracy of sensing the output signal (e.g., the output voltage VOUT and/or the output current Io) of the power management apparatus 2100 and in another aspect to improve the accuracy of regulating the output signal (e.g., the output voltage VOUT and/or the output current Io) to a predetermined value. In yet another aspect, using the integrated resistive element as described with various embodiments of the present disclosure to implement the sensing unit 160 of the power management apparatus may help to achieve improved performance with good die or chip size (at least without greatly increasing the die or chip size).

In an embodiment, the power switching unit 110 may be implemented and fabricated in an integrated circuit (“IC”) die 210. In an embodiment, the control unit 140 and the sensing unit 160 may be fabricated and/or integrated on the same IC die 210 as the power switching unit 110. In an alternative embodiment, the control unit 140 and the sensing unit 160 may be fabricated and/or integrated on a separate IC die from that of the power switching unit 110. In still an alternative embodiment, the control unit 140 may be provided from other circuitry of the application system where the power management apparatus 100 may be used. For instance, a micro controller in the application system may be configured to implement the functionality of the control unit 140.

In an embodiment, a capacitive energy storage unit 150 may be coupled to the output terminal OUT. The capacitive energy storage unit 150 may include one or more capacitors for example and may be operated as an output filter to smooth the output voltage VOUT at the output terminal OUT. One of ordinary skill in the art would understand that the power management apparatus 100 may include other active components and/or passive components that may not be addressed in detail here.

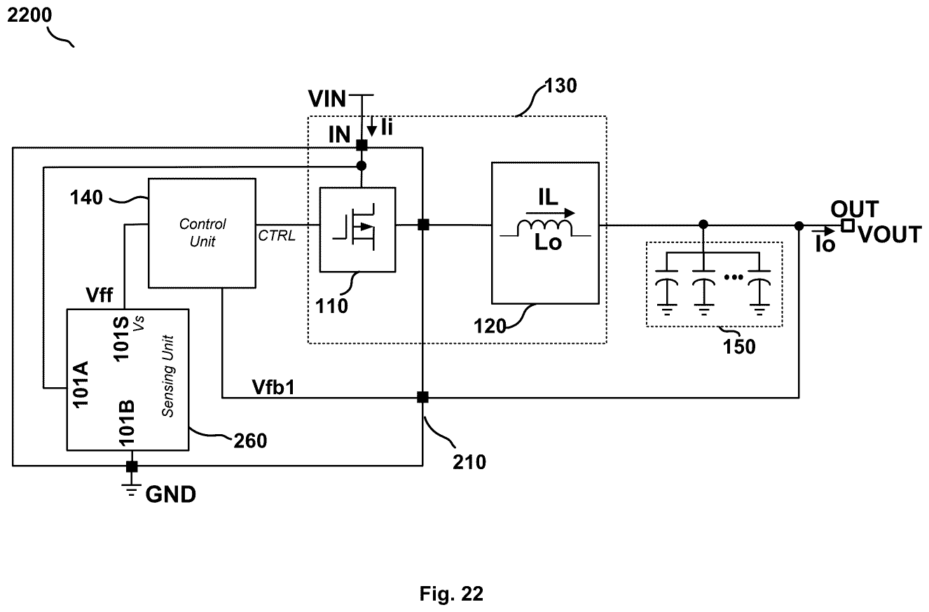

FIG. 22 illustrates a block diagram of an electronic apparatus including a power management apparatus 2200 in accordance with an alternative embodiment of the present invention. Those skilled in the art would understand that substantial descriptions made to the power management apparatus 2100 with reference to FIG. 21 are applicable to the example of FIG. 22 and need not to be addressed again here for simplicity. Difference in one aspect may lie in that the power management apparatus 2200 includes a sensing unit 260 configured to be operative to sense the input signal (e.g., the input voltage VIN and/or the input current Ii) to provide the information indicative of the input signal as shown in the example of FIG. 22. The sensing unit 260 may be implemented with any one of the integrated resistive elements that can be configured as a resistive sensing unit in accordance with various embodiments of the present invention as described with reference to FIG. 1 through FIG. 20A. In such an application example, the integrated resistive element that is used to implement the sensing unit 260 is configured to have its first terminal 101A operative to be electrically coupled to the input terminal IN to receive the input signal, its second terminal 101B operative to be electrically connected to the reference ground GND, and its sensing terminal 101S operative to be configured to provide the sensing voltage Vs as a feedforward signal Vff that may be provided to the control unit 140 as the information indicative of the input signal. Similar as the sensing unit 160, the sensing unit 260 may be fabricated and/or integrated on the same IC die 210 as the power switching unit 110 or alternatively be fabricated and/or integrated together with the control unit 140 on a separate IC die from that of the power switching unit 110. In another aspect, compared to the power management apparatus 2100 described with reference to FIG. 21, the control unit 140 of the power management apparatus 2200 may receive an output feedback signal Vfb1 carrying the information indicative of the output signal (e.g., the output voltage VOUT and/or the output current Io). The output feedback signal Vfb1 may, in an embodiment, be provided from a feedback circuit coupled to the output terminal OUT, or in another embodiment be provided from a sensing unit 160 as described with the example of FIG. 21 (i.e., with the feedback signal Vfb used as the output feedback signal Vfb1), or in still another embodiment be provided directly from the output terminal OUT (i.e., with the output signal used as the output feedback signal Vfb1).

The power management apparatus 2200 having the sensing unit 260 implemented with an integrated resistive element as described with various embodiments of the present invention may advantageously improve an accuracy of sensing the input voltage VIN and improve the accuracy of regulating the output voltage VOUT to a predetermined value.

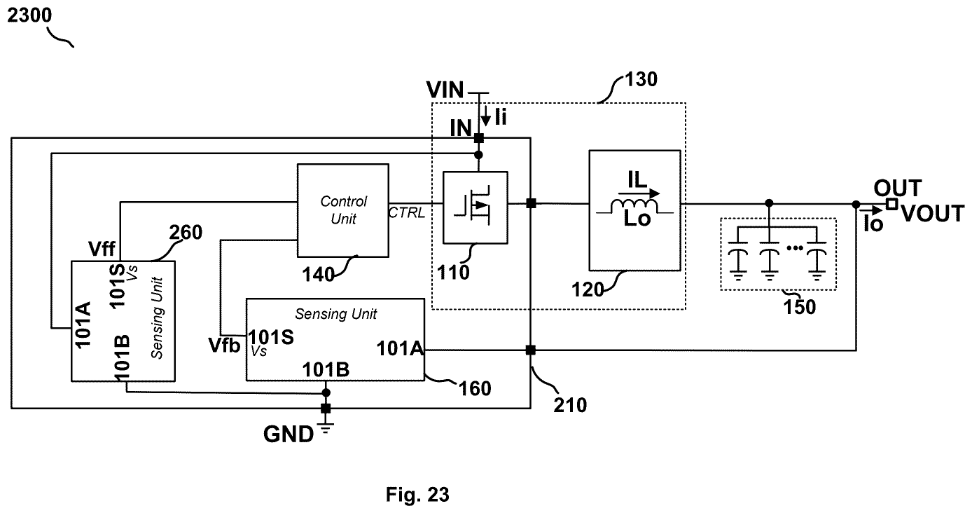

FIG. 23 illustrates a block diagram of a power management apparatus 2300 in accordance with an alternative embodiment of the present invention. Those skilled in the art would understand that substantial descriptions made to the power management apparatus 2100 and 2200 with reference to FIG. 21 and FIG. 22 are applicable to the example of FIG. 23 and need not to be addressed again here for simplicity. The power management apparatus 2300 includes the sensing unit 160 configured to be operative to sense the output signal (e.g., the output voltage VOUT and/or the output current Io) to provide the information indicative of the output signal just as described with reference to FIG. 21 and the sensing unit 260 configured to be operative to sense the input signal (e.g., the input voltage VIN and/or the input current Ii) to provide the information indicative of the input signal just as described with reference to FIG. 22.

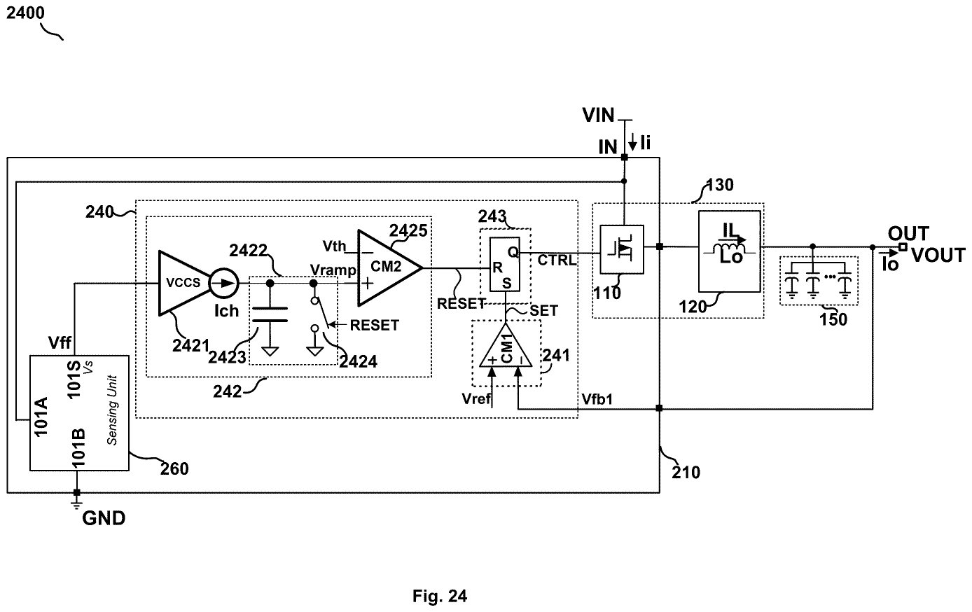

FIG. 24 illustrates a block diagram of a power management apparatus 2400 in accordance with an alternative embodiment of the present invention. The power management apparatus 2400 includes the sensing unit 260 configured to be operative to sense the input signal (e.g., the input voltage VIN and/or the input current Ii) to provide the information indicative of the input signal just as described with reference to FIG. 22. Substantial descriptions made to the power management apparatus 2200 with reference to FIG. 22 are applicable to the example of FIG. 24 and need not to be addressed again here for simplicity. The power management apparatus 2400 includes a control unit 240 which may be considered as an exemplary embodiment of the control unit 140 of FIG. 22.

The control unit 240 may include a set control module 241, a reset control module 242 and a logic control module 243. The set control module 241 may be configured to be operative to receive a reference signal Vref at a first input terminal, to receive an output feedback signal Vfb1 carrying information indicative of the output signal (e.g., the output voltage VOUT or the output current Io) at a second input terminal, and to compare the output feedback signal Vfb1 with the reference signal Vref to provide a set control signal SET at an output terminal. In an embodiment, the output feedback signal Vfb1 may be provided from a feedback circuit coupled to the output terminal OUT, or in another embodiment be provided from a sensing unit 160 as described with the example of FIG. 21 (i.e., with the feedback signal Vfb used as the output feedback signal Vfb1). In an alternative embodiment, the second input terminal of the set control module 241 may receive the output signal as the output feedback signal Vfb1. Although the set control module 241 is illustratively shown to comprise a first comparator CM1 in the exemplary embodiment of FIG. 24, it should be understood that this is not intended to be limiting, the set control module 241 obviously may have various other implementation variants that can practice the comparison functionality.

The reset control module 242 is coupled to the sensing unit 260 to receive the feedforward signal Vff indicative of the input signal (e.g., the input voltage VIN or the input current Ii) from the sensing unit 260. The reset control module 242 may be configured to be operative to provide a reset control signal RESET based on the feedforward signal Vff and a threshold signal Vth having a predetermined threshold voltage value. The reset control signal RESET may be a pulse width modulated signal having a pulse width indicative of the on time Ton. The reset control module 242 is configured to be operative to regulate the pulse width of the reset control signal RESET indicative of the on time Ton to vary with the input signal so that the on time Ton can dynamically track the change in the input signal and a substantially fixed (or substantially constant) operation frequency Top can be achieved within a relatively wide variation range of the input signal (e.g., the input voltage VIN or the input current Ii). For instance, the input voltage VIN may vary with a variation range of 20V to 70V in an embodiment while the operation frequency Top of the power management apparatus 2400 can be maintained to be substantially fixed (or substantially constant). This is at least in one aspect owning to the use of the sensing unit 260 which can sense the input signal (e.g., the input voltage VIN or the input current Ii) with improved accuracy and good linearity to provide the feedforward signal Vff tracking the input signal in a more accurate and substantially linear manner. A substantially fixed (or substantially constant) operation frequency Top is beneficial to various performance of the power management apparatus 2400 including but not limited to a higher power conversion efficiency, improved stability, relatively fixed ripple in the output voltage VOUT, lower EMI, etc.

In the example of FIG. 24, the reset control module 242 is illustrated to include a voltage controlled current source (VCCS) 2421, a ramp generation circuit 2422, and a comparison circuit 2425. The VCCS 2421 is configured to be operative to receive the feedforward signal Vff and to provide a charging current Ich controlled by the feedforward signal Vff so that the charging current Ich is proportional to the input signal (e.g., the input voltage VIN or the input current Ii). The ramp generation circuit 2422 is configured to be operative to provide a ramp signal Vramp based on charging a ramp capacitor 2423 with the charging current Ich and discharging the ramp capacitor 2423 in response to the reset control signal RESET. The comparison circuit 2425 is configured to be operative to compare the ramp signal Vramp with the threshold signal Vth to provide the reset control signal RESET. It should be understood that configuration of the reset control module 242 described here with the particular example shown in FIG. 24 is just to provide an example and not intended to be limiting, the reset control module 242 obviously may have various other implementation variants that can provide the reset control signal RESET indicative of the on time Ton to vary with the input voltage VIN.

The logic control module 243 is configured to be operative to receive the set control signal SET and the reset control signal RESET and to provide the control signal CTRL based on the set control signal SET and the reset control signal RESET. The control unit 240 may be configured to be operative to control the switching unit 110 to couple the inductive energy storage device 120 such that energy can be transferred from the input terminal IN to the inductive energy storage device 120 for energy storage based on the control signal CTRL in response to the set control signal SET, and may further be configured to be operative to control the switching unit 110 to couple the inductive energy storage device 120 such that energy can be transferred from the inductive energy storage device 120 to the output terminal OUT for energy release based on the control signal CTRL in response to the reset control signal RESET.

In the example of FIG. 24, the logic control module 243 is illustrated to include an RS flip-flop having a set input terminal S, a reset input terminal R and an output terminal Q, wherein the RS flip-flop RS1 is configured to receive the ON control signal SETON at the set input terminal S, to receive the OFF control signal SETOFF at the reset input terminal R, and to provide the control signal CTRL at the output terminal Q. However, this is just to provide an example and not intended to be limiting, the logic control module 243 obviously may have various other implementation variants that can generate the control signal CTRL based on the set control signal SET and the reset control signal RESET.

Those of ordinary skill in the art would understand that the control unit 240 as described above with reference to FIG. 24 may alternatively be used as an exemplary embodiment of the control unit 140 of FIG. 23. For this situation, the feedback signal Vfb received at the second input terminal of the set control module 241 may be provided from the resistive sensing unit 160 of FIG. 23.

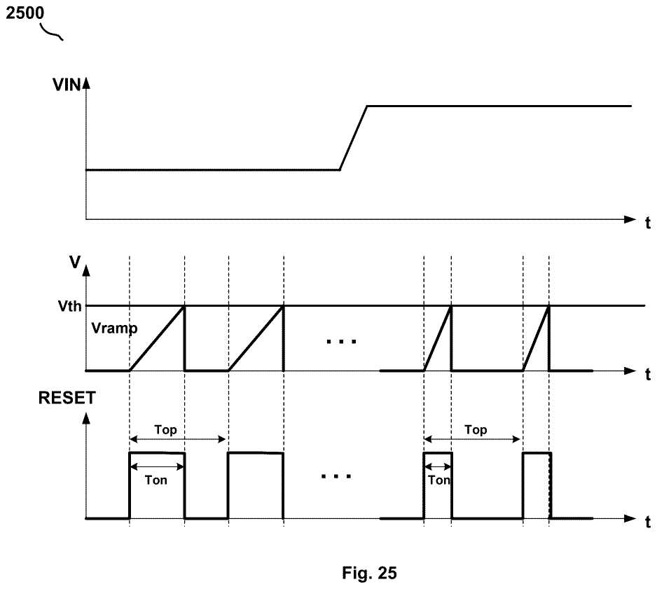

FIG. 25 illustrates a waveform diagram of several signals of the power management apparatus 2400 during operation. It can be seen from FIG. 25 that the pulse width of the reset signal RESET indicative of the on time Ton can dynamically change with the input voltage VIN, for instance, decrease when the input voltage VIN increases and increase when the input voltage VIN decreases, so that the operation frequency Top may be maintained substantially fixed (or substantially constant) when the input voltage VIN changes.

Although a power management apparatus 2400 with the control unit 240 configured to implement an on time control scheme is provided in the embodiment of FIG. 24 as an example, one of ordinary skill in the art would understand that in other embodiments, power management apparatus as described with reference to FIG. 21 to FIG. 23 with the control unit 140 configured to implement other control schemes such an off time control scheme, a peak current control scheme, a valley current control scheme, an average current mode control scheme, a voltage mode control scheme, a ripple based control scheme, a V² current mode control scheme, etc. do not depart from the spirit and scope of the present disclosure.

In addition to being used in applications such as the power management apparatuses described with FIG. 21 to FIG. 25, the integrated resistive elements that may be configured as the resistive sensing units according to various embodiments of the present disclosure may find a large variety of other application scenarios that require signal sensing. Therefore, electronic apparatuses that include at least one of the resistive sensing units of various embodiments of the present disclosure to implement a large variety of functionality for various applications are within the spirit and scope of various embodiments of the present disclosure.

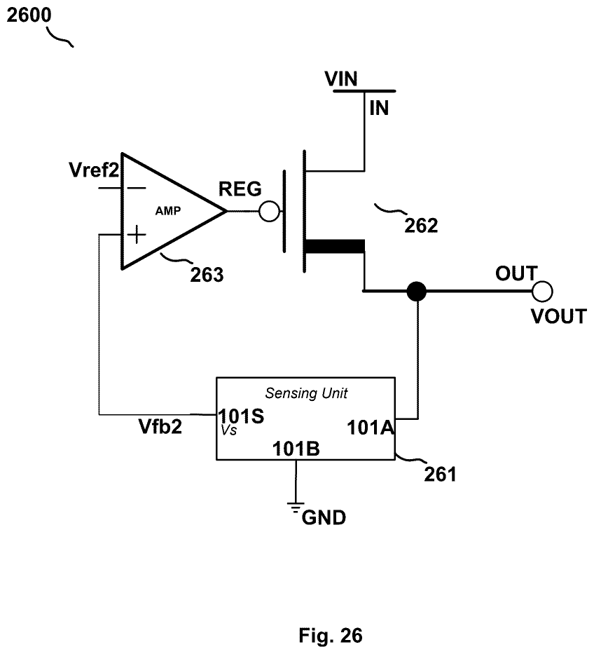

For instance, FIG. 26 illustrates a block diagram of an electronic apparatus including a linear voltage regulator 2600 in accordance with an embodiment of the present invention. Persons of ordinary skill in the art would understand that the linear voltage regulator 2600 is one type of power management apparatus itself and may be provided as a single device or be used and integrated into a larger power management apparatus such as those described with reference to the embodiments of FIG. 21 to FIG. 25. The linear voltage regulator 2600 may include a sensing unit 261 configured to be operative to sense an output voltage VOUT at an output terminal OUT of the linear voltage regulator 2600. The sensing unit 261 is further configured to provide a regulator feedback signal Vfb2 indicative of the output voltage VOUT of the linear voltage regulator 2600. The sensing unit 261 may be implemented with any one of the integrated resistive elements that can be configured as a resistive sensing unit in accordance with various embodiments of the present invention as described with reference to FIG. 1 through FIG. 20A. In such an application example, the integrated resistive element that is used to implement the sensing unit 261 is configured to have its first terminal 101A operative to be electrically coupled to the output terminal OUT of the linear voltage regulator 2600, its second terminal 101B operative to be electrically connected to the reference ground GND, and its sensing terminal 101S operative to be configured to provide the sensing voltage Vs as the feedback signal Vfb that may be provided to a regulator control unit 263. The regulator control unit 263 may be configured to be operative to provide a regulation control signal REG based on a difference between the regulator feedback signal Vfb2 and a regulation reference signal Vref2. The linear voltage regulator 2600 further includes a regulation transistor 262 coupled between an input terminal IN of the linear voltage regulator 2600 and the output terminal OUT of the linear voltage regulator 2600. The regulator control unit 263 may be configured to control the regulation transistor 262 based on the regulation control signal REG to regulate the output voltage VOUT of the linear voltage regulator 2600. Using the sensing unit 261 implemented with any one of the integrated resistive elements as described with reference to FIG. 1 through FIG. 20A may at least advantageously have an improved accuracy of regulating the output voltage VOUT of the linear voltage regulator 2600 to have a desired voltage value.

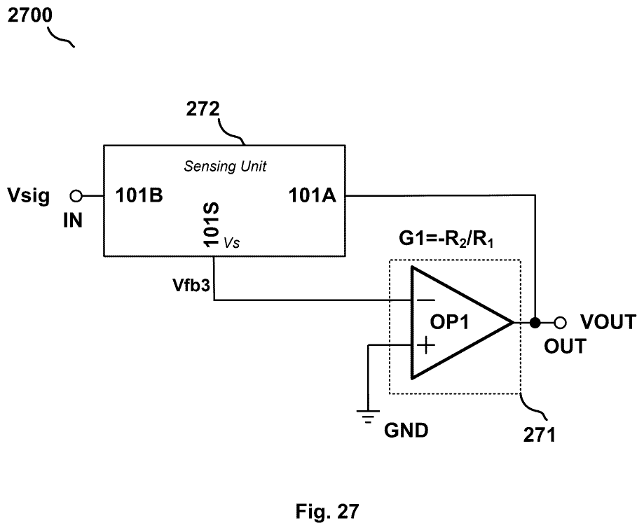

For another instance, FIG. 27 illustrates a block diagram of an electronic apparatus including an audio amplifier 2700 in accordance with an embodiment of the present invention. To provide an example, the audio amplifier 2700 includes a first amplification unit 271 and a sensing unit 272. The audio amplifier 2700 may have a signal input terminal IN and a signal output terminal OUT. The signal input terminal IN may be configured to be operative to receive an input signal Vsig indicative of an audio input, and the signal output terminal OUT may be configured to be operative to provide an output signal VOUT indicative of an audio output. The audio amplifier 2700 may be configured to be operative to provide an amplification gain G1 to amplify the input signal Vsig with the amplification gain G1 to provide the output signal VOUT. That is, VOUT=G1*Vsig. In an embodiment, the audio amplifier 2700 is configured to have the amplification gain G1 being regulated by the sensing unit 272.

In an embodiment, the first amplification unit 271 may include a first operational amplifier OP1 having a first input terminal (e.g., a non-inverting input terminal “+”), a second input terminal (e.g., an inverting input terminal “−”) and an output terminal. In the example of FIG. 27, the first input terminal of the first amplification unit 271 is connected to a reference ground GND, the second input terminal of the first amplification unit 271 is connected to the sensing unit 272, and the output terminal of the first amplification unit 271 is embodied as the signal output terminal OUT of the audio amplifier 2700.

In an embodiment, the sensing unit 272 may be coupled between the signal input terminal IN and the signal output terminal OUT of the audio amplifier 2700 and may be configured to be operative to provide an audio feedback signal Vfb3 indicative of a difference between the output signal VOUT and the input signal Vsig. The sensing unit 272 may be implemented with any one of the integrated resistive elements that can be configured as a resistive sensing unit in accordance with various embodiments of the present invention as described with reference to FIG. 1 through FIG. 20A. In such an application example, the integrated resistive element that is used to implement the sensing unit 272 is configured to have its first terminal 101A operative to be electrically coupled to the signal output terminal OUT of the audio amplifier 2700, its second terminal 101B operative to be electrically coupled to the signal input terminal IN of the audio amplifier 2700, and its sensing terminal 101S operative to be configured to provide the sensing voltage Vs as the audio feedback signal Vfb3 that may be provided to the second input terminal of the first amplification unit 271.

For such an exemplary configuration, the amplification gain G1 of the audio amplifier 2700 may be regulated by the sensing unit 272, for instance, the amplification gain G1 may be adjusted by adjusting the sensing gain Ga of the integrated resistive element that is used to implement the sensing unit 272, wherein the sensing gain Ga is depending on the resistance ratio K=R2/R1. For the exemplary configuration of the audio amplifier 2700 shown in FIG. 27, the amplification gain G1 of the audio amplifier 2700 may be expressed by G1=−R2/R1. Using the sensing unit 272 implemented with any one of the integrated resistive elements as described with reference to FIG. 1 through FIG. 20A may at least advantageously improve a linearity or a stability of the amplification gain G1 of the audio amplifier 2700, so that the audio output can track the audio input with reduced loss and distortion.

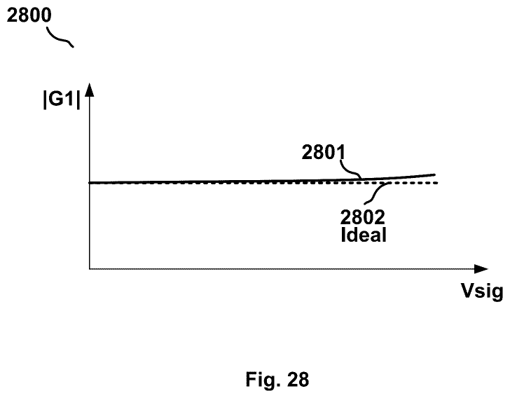

FIG. 28 illustrates a waveform diagram 2800 illustrating a practical curve 2801 of an amplitude of the amplification gain G1 of the audio amplifier 2700 versus the input signal Vsig provided to the audio amplifier 2700 and a theoretically ideal curve 2802 of the amplitude of the amplification gain G1 of the audio amplifier 2700 versus the input signal Vsig. It can be seen that the practical curve 2801 can follow the ideal curve 2802 with very low distortion, which means that the audio amplifier 2700 may have the audio output well tracking the audio input with reduced loss and distortion in practical applications.

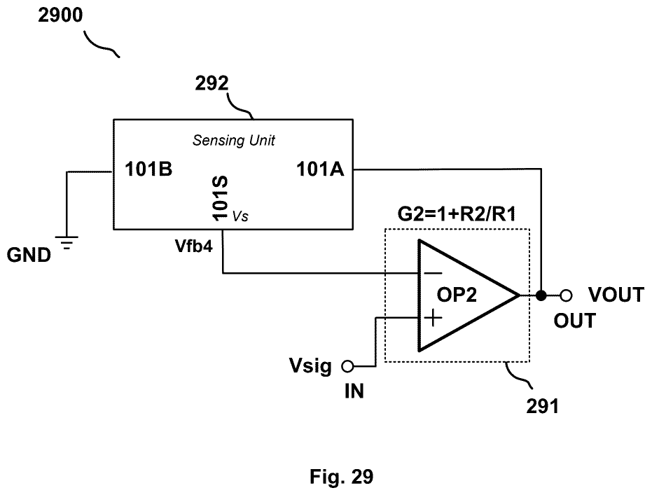

For still another instance, FIG. 29 illustrates a block diagram of an electronic apparatus including an audio amplifier 2900 in accordance with an alternative embodiment of the present invention. To provide an example, the audio amplifier 2900 includes a second amplification unit 291 and a sensing unit 292. The audio amplifier 2900 may have a signal input terminal IN and a signal output terminal OUT. The signal input terminal IN may be configured to be operative to receive an input signal Vsig indicative of an audio input, and the signal output terminal OUT may be configured to be operative to provide an output signal VOUT indicative of an audio output. The audio amplifier 2900 may be configured to be operative to provide an amplification gain G2 to amplify the input signal Vsig with the amplification gain G2 to provide the output signal VOUT. That is, VOUT=G2*Vsig. In an embodiment, the audio amplifier 2900 is configured to have the amplification gain G2 being regulated by the sensing unit 292.

In an embodiment, the second amplification unit 291 may include a second operational amplifier OP2 having a first input terminal (e.g., a non-inverting input terminal “+”), a second input terminal (e.g., an inverting input terminal “−”) and an output terminal. In the example of FIG. 29, the first input terminal of the second amplification unit 291 is configured as the signal input terminal IN of the audio amplifier 2900, the second input terminal of the second amplification unit 291 is connected to the sensing unit 292, and the output terminal of the second amplification unit 291 is configured as the signal output terminal OUT of the audio amplifier 2900.

In an embodiment, the sensing unit 292 may be coupled between signal output terminal OUT of the audio amplifier 2900 and a reference ground GND and may be configured to provide an audio feedback signal Vfb4 indicative of a difference between the output signal VOUT and the input signal Vsig. The sensing unit 292 may be implemented with any one of the integrated resistive elements that can be configured as a resistive sensing unit in accordance with various embodiments of the present invention as described with reference to FIG. 1 through FIG. 20A. In such an application example, the integrated resistive element that is used to implement the sensing unit 292 is configured to have its first terminal 101A operative to be electrically coupled to the signal output terminal OUT of the audio amplifier 2900, its second terminal 101B operative to be electrically connected to the reference ground GND, and its sensing terminal 101S operative to be configured to provide the sensing voltage Vs as the audio feedback signal Vfb4 that may be provided to the second input terminal of the second amplification unit 291.

For such an exemplary configuration, the amplification gain G2 of the audio amplifier 2900 may be regulated by the sensing unit 292, for instance, the amplification gain G2 may be adjusted by adjusting the sensing gain Ga of the integrated resistive element that is used to implement the sensing unit 292, wherein the sensing gain Ga is depending on the resistance ratio K=R2/R1. For the exemplary configuration of the audio amplifier 2900 shown in FIG. 29, the amplification gain G2 of the audio amplifier 2900 may be expressed by G2=1+R2/R1. Using the sensing unit 292 implemented with any one of the integrated resistive elements as described with reference to FIG. 1 through FIG. 20A may at least advantageously improve a linearity or a stability of the amplification gain G2 of the audio amplifier 2900, so that the audio output can track the audio input with reduced loss and distortion.

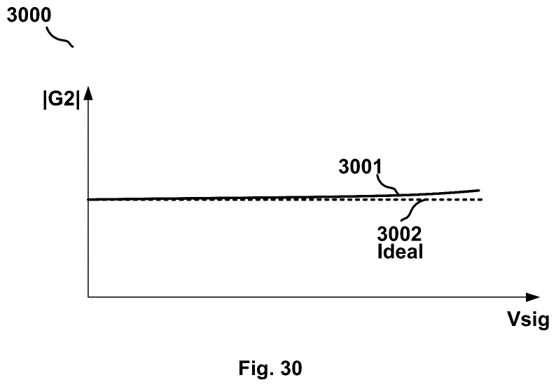

FIG. 30 illustrates a waveform diagram 3000 illustrating a practical curve 3001 of an amplitude of the amplification gain G2 of the audio amplifier 2900 versus the input signal Vsig provided to the audio amplifier 2900 and a theoretically ideal curve 3002 of the amplitude of the amplification gain G2 of the audio amplifier 2900 versus the input signal Vsig. It can be seen that the practical curve 3001 can follow the ideal curve 3002 with very low distortion, which means that the audio amplifier 2900 may have the audio output well tracking the audio input with reduced loss and distortion in practical applications.

There are many other application scenarios that may include and use the integrated resistive elements according to various embodiments of the present disclosure and cannot be exhaustively addressed here, yet do not depart from the spirit and scope of various embodiments of the present disclosure.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments.

What is claimed is:

1. An integrated resistive element, comprising:
a first well of a second conductivity type formed in a substrate of a first conductivity type, the second conductivity type being opposite to the first conductivity type;
a second well of the second conductivity type formed in the substrate, the second well being separated and electrically isolated from the first well; and
a plurality of resistive segments including a first portion disposed in or on the first well and a second portion disposed in or on the second well; wherein
the second portion is for being electrically coupled between a first terminal and a sensing terminal of the integrated resistive element; and wherein
the first portion is for being electrically coupled between the sensing terminal and a second terminal of the integrated resistive element.

2. The integrated resistive element of claim 1, wherein the plurality of resistive segments are substantially identical to each other.

3. The integrated resistive element of claim 1, further comprising:
a first well bus for being electrically coupled to the first well; and
a second well bus for being electrically coupled to the second well.

4. The integrated resistive element of claim 1, further comprising:
a first well bus formed in a first conductive routing layer disposed atop a first interlayer dielectric layer on the substrate; and
a second well bus formed in the first conductive routing layer; wherein the second well bus is separated and electrically isolated from the first well bus.

5. The integrated resistive element of claim 4, wherein:
the first well bus is routed above and along a perimeter of the first well when inspected in a plan view; and wherein
the second well bus is routed above and along a perimeter of the second well when inspected in the plan view.

6. The integrated resistive element of claim 1, further comprising:
a first set of conductive connecting segments for electrically coupling a first set of resistive segments among the plurality of resistive segments in series; and
a second set of conductive connecting segments for electrically coupling a second set of resistive segments among the plurality of resistive segments in series.

7. The integrated resistive element of claim 6, further comprising:
a first well bus routed surrounding the first set of conductive connecting segments; and
a second well bus routed surrounding the second set of conductive connecting segments.

8. The integrated resistive element of claim 6, wherein:
the first set of conductive connecting segments are formed in a first conductive routing layer and are electrically coupled to the first set of resistive segments through a first plurality of interlayer routing elements formed in a first interlayer dielectric layer that is disposed between the first conductive routing layer and the substrate; and wherein
the second set of conductive connecting segments are formed in the first conductive routing layer and are electrically coupled to the second set of resistive segments through a second plurality of interlayer routing elements formed in the first interlayer dielectric layer.

9. The integrated resistive element of claim 1, wherein the sensing terminal, the first terminal and the second terminal of the integrated resistive element are formed in a second conductive routing layer formed atop a second interlayer dielectric layer that is disposed on a first interlayer dielectric layer on the substrate.

10. The integrated resistive element of claim 9, further comprising:
a first well terminal formed in the second conductive routing layer and electrically coupled to the first well through interlayer routing elements formed in the first interlayer dielectric layer and the second interlayer dielectric layer; and
a second well terminal formed in the second conductive routing layer and electrically coupled to the second well through interlayer routing elements formed in the first interlayer dielectric layer and the second interlayer dielectric layer.

11. The integrated resistive element of claim 1, wherein the integrated resistive element is operative to receive a first bias voltage for biasing the first well and a second bias voltage for biasing the second well.

12. The integrated resistive element of claim 11, wherein the first bias voltage is set to be in a range from a second voltage that is applied to the second terminal of the integrated resistive element to the second bias voltage or to be in a range between the second voltage and a sensing voltage at the sensing terminal; or wherein the first bias voltage is substantially set to a second voltage applied to the second terminal of the integrated resistive element or to a sensing voltage at the sensing terminal or to be approaching to a middle value between the sensing voltage and the second voltage with a predetermined deviation margin.

13. The integrated resistive element of claim 11, wherein the first bias voltage is derived from a sensing voltage at the sensing terminal with a first scale-down coefficient.

14. The integrated resistive element of claim 13, wherein the first scale-down coefficient is in a range from ⅓ to ⅔ or is substantially set to ½ with a predetermined deviation margin.

15. The integrated resistive element of claim 11, wherein the first terminal is operative to receive a first voltage Vtop, the second terminal is operative to receive a second voltage Vbot and the sensing terminal is operative to provide a sensing voltage Vs; and wherein the second bias voltage is set to be in a range between the first bias voltage and the first voltage Vtop, or to be in a range between the sensing voltage Vs and the first voltage Vtop, or to be in a range from (Vab/3+Vbot) to (2*Vab/3+Vbot), or to be in a range from [(Vtop−Vs)/3+Vs] to [2*(Vtop−Vs)/3+Vs], or to be substantially approaching to a middle value between the sensing voltage Vs and the first voltage Vtop with a predetermined deviation margin, or to be substantially approaching to a middle value between the first bias voltage and the first voltage Vtop with a predetermined deviation margin, or to be substantially approaching to a middle value between the second voltage Vbot and the first voltage Vtop with a predetermined deviation margin.

16. The integrated resistive element of claim 11, wherein the second bias voltage is derived from a first voltage applied to the first terminal of the integrated resistive element with a second scale-down coefficient.

17. The integrated resistive element of claim 16, wherein the second scale-down coefficient is in a range from ⅓ to ⅔ or is substantially set to ½ with a predetermined deviation margin.

18. The integrated resistive element of claim 1, further comprising:
a well contact region of the second conductivity formed in each one of the first well and the second well and having a higher dopant concentration than the first well and the second well.

19. The integrated resistive element of claim 1, wherein each one of the plurality of resistive segments includes a poly-silicon segment.

20. The integrated resistive element of claim 19, further comprising:
an insulation layer formed in each one of the first well and the second well, wherein the insulation layer in the first well is disposed under the first set of resistive segments while the insulation layer in the second well is disposed under the second set of resistive segments.

21. The integrated resistive element of claim 1, wherein the first portion includes a first set of resistive segments among the plurality of resistive segments and the second portion includes a second set of resistive segments among the plurality of resistive segments, and wherein each one of the first set of resistive segments includes a doped region of the first conductivity type formed in the first well and having a higher dopant concentration than the first well, and wherein each one of the second set of resistive segments includes a doped region of the first conductivity type formed in the second well and having a higher dopant concentration than the second well.

22. The integrated resistive element of claim 1, wherein the second well is configured to be self-biased from the second portion of the plurality of resistive segments or wherein the second well is electrically coupled to a second well biasing terminal that is disposed between and connected to a third portion and a fourth portion of the second portion of the plurality of resistive segments.

23. The integrated resistive element of claim 22, wherein the third portion includes a third set of resistive segments of the second portion, and wherein the fourth portion includes a fourth set of resistive segments of the second portion, and wherein the second well biasing terminal is electrically coupled to a starting one resistive segment in the fourth portion and to an ending one resistive segment in the third portion.

24. The integrated resistive element of claim 22, wherein the first terminal is configurable to receive a first voltage Vtop, the second terminal is configurable to receive a second voltage Vbot and the sensing terminal is configurable to provide a sensing voltage Vs, and wherein the second portion of the plurality of resistive segments has a second resistance R2, and wherein the third portion of the second portion has a third resistance R3, and wherein the second well biasing terminal is operative to provide a second bias voltage Vbs2 that is expressed by Vbs2=(Vtop−Vs)*R3/R2+Vs.

25. The integrated resistive element of claim 1, wherein the first well is electrically coupled to the sensing terminal or to the second terminal of the integrated resistive element, or wherein the first well is configured to be self-biased from the first portion of the plurality of resistive segments, or wherein the first well is electrically coupled to a first well biasing terminal that is disposed between and connected to a fifth portion and a sixth portion of the first portion of the plurality of resistive segments.

26. The integrated resistive element of claim 25, wherein the fifth portion includes a fifth set of resistive segments of the first portion, and wherein the sixth portion includes a sixth set of resistive segments of the first portion, and wherein the first well biasing terminal is electrically coupled to a starting one resistive segment in the sixth portion and to an ending one resistive segment in the fifth portion.

27. The integrated resistive element of claim 1, further comprising:
a protection circuit, electrically coupled between the sensing terminal and the second portion of the plurality of resistive segments of the integrated resistive element.

28. The integrated resistive element of claim 28, wherein the protection circuit is formed in a third well that is formed in the substrate and separated from the first well and the second well.

29. The integrated resistive element of claim 28, wherein the protection circuit is configured to be operative to enable or disable an electrical coupling or connection between the sensing terminal and the second portion of the plurality of resistive segments of the integrated resistive element.

30. The integrated resistive element of claim 28, wherein the protection circuit includes a controllable transistor.

31. A power management apparatus, comprising:
a first resistive sensing unit including a first integrated resistive element of claim 1, wherein the first terminal of the first integrated resistive element is operative to be electrically coupled to an output terminal of the power management apparatus to receive an output signal, the second terminal of the first integrated resistive element is operative to be electrically connected to a reference ground, and the sensing terminal of the first integrated resistive element is operative to provide a feedback signal indicative of the output signal; or
a second resistive sensing unit including a second integrated resistive element of claim 1, wherein the first terminal of the second integrated resistive element is operative to be electrically coupled to an input terminal of the power management apparatus to receive an input signal, the second terminal of the second integrated resistive element is operative to be electrically connected to a reference ground, and the sensing terminal of the second integrated resistive element is operative to provide a feedforward signal indicative of the input signal.

32. The power management apparatus of claim 31, further comprising:
a power switching unit operative to regulate energy or power transmission between the input terminal of the power management apparatus and the output terminal of the power management apparatus in response to at least one control signal.

33. The power management apparatus of claim 32, wherein the power switching unit is formed in an integrated circuit die that includes the first resistive sensing unit or the second resistive sensing unit.

34. The power management apparatus of claim 31, further comprising:
a control unit operative to receive the feedback signal or the feedforward signal, and further operative to provide at least one control signal for controlling a power switching unit of the power management apparatus.

35. The power management apparatus of claim 34, wherein the control unit is formed in an integrated circuit die that includes the first resistive sensing unit or the second resistive sensing unit.

36. The power management apparatus of claim 34, wherein the control unit includes:
a set control module configured to be operative to receive a reference signal and an output feedback signal indicative of the output signal and to compare the output feedback signal with the reference signal to provide a set control signal, wherein the output feedback signal is provided from a feedback circuit coupled to the output terminal of the power management apparatus or is the feedback signal provided from the first resistive sensing unit or is the output signal;
a reset control module coupled to the second resistive sensing unit to receive the feedforward signal, and configured to be operative to provide a reset control signal based on the feedforward signal and a threshold signal and to regulate a pulse width of the reset control signal to vary with the input signal; and
a logic control module configured to be operative to receive the set control signal and the reset control signal and to provide the at least one control signal based on the set control signal and the reset control signal.

37. The power management apparatus of claim 36, wherein the reset control module includes:
a voltage controlled current source configured to be operative to receive the feedforward signal and to provide a charging current controlled by the feedforward signal;
a ramp generation circuit configured to be operative to provide a ramp signal based on charging a ramp capacitor with the charging current and discharging the ramp capacitor in response to the reset control signal; and
a comparison circuit configured to be operative to compare the ramp signal with the threshold signal to provide the reset control signal.

38. The power management apparatus of claim 31, wherein the power management apparatus includes both the first resistive sensing unit and the second resistive sensing unit.

39. The power management apparatus of claim 38, further comprising:
a control unit operative to receive the feedback signal and the feedforward signal, and further operative to provide at least one control signal for controlling a power switching unit of the power management apparatus.

40. The power management apparatus of claim 31, further comprising:
a linear voltage regulator operative to provide a regulator output voltage, wherein the linear voltage regulator includes a third resistive sensing unit including a third integrated resistive element of claim 1, wherein the first terminal of the third integrated resistive element is operative to be electrically coupled to an output terminal of the linear voltage regulator, the second terminal of the third integrated resistive element is operative to be electrically connected to the reference ground, and the sensing terminal of the third integrated resistive element is operative to provide a regulator feedback signal indicative of the regulator output voltage.

41. The power management apparatus of claim 40, wherein the linear voltage regulator further includes:
a regulation transistor coupled between an input terminal of the linear voltage regulator and the output terminal of the linear voltage regulator; and
a regulator control unit configured to be operative to provide a regulation control signal to control the regulation transistor based on a difference between the regulator feedback signal and a regulation reference signal.

42. The power management apparatus of claim 40, wherein the first resistive sensing unit and the second resistive sensing unit are omitted.

43. An electronic apparatus including an audio amplifier, comprising:
a resistive sensing unit including an integrated resistive element of claim 1 and coupled between a signal input terminal and a signal output terminal of the audio amplifier, wherein the resistive sensing unit is configured to be operative to provide an audio feedback signal indicative of a difference between an output signal at the signal output terminal and an input signal at the signal input terminal.

44. The electronic apparatus of claim 43, wherein the first terminal of the integrated resistive element is operative to be electrically coupled to the signal output terminal, the second terminal of the integrated resistive element is operative to be electrically coupled to the signal input terminal, and the sensing terminal of the integrated resistive element is operative to provide the audio feedback signal.

45. The electronic apparatus of claim 43, wherein the audio amplifier further includes:
a first amplification unit having a first input terminal connected to a reference ground, a second input terminal connected to the resistive sensing unit to receive the audio feedback signal, and an output terminal embodied as the signal output terminal of the audio amplifier.

46. The electronic apparatus of claim 43, wherein the audio amplifier is operative to provide an amplification gain to amplify the input signal with the amplification gain to provide the output signal, and wherein the resistive sensing unit is operative to regulate the amplification gain.

47. The electronic apparatus of claim 46, wherein the amplification gain depends on a resistance ratio between a first resistance of the first portion of the plurality of resistive segments and a second resistance of the second portion of the plurality of resistive segments.

48. The electronic apparatus of claim 46, wherein the resistive sensing unit including the integrated resistive element of claim 1 is coupled between the signal output terminal of the audio amplifier and a reference ground instead.

49. The electronic apparatus of claim 48, wherein the first terminal of the integrated resistive element is operative to be electrically coupled to the signal output terminal, the second terminal of the integrated resistive element is operative to be electrically connected to the reference ground, and the sensing terminal of the integrated resistive element is operative to provide the audio feedback signal.

50. The electronic apparatus of claim 48, wherein the audio amplifier further includes:
a second amplification unit having a first input terminal configured as the signal input terminal of the audio amplifier, a second input terminal connected to the resistive sensing unit to receive the audio feedback signal, and an output terminal embodied as the signal output terminal of the audio amplifier.
